(19) United States
(12) Patent Application Publication
(10) Pub. No.: US 2025/0344474 A1
(43) Pub. Date: Nov. 6, 2025

(54) SEMICONDUCTOR DEVICE

(71) Applicant: ROHM CO., LTD., Kyoto-shi (JP)

(72) Inventors: Shingo OTA, Kyoto-shi (JP); Yusuke YOSHIHARA, Kyoto-shi (JP)

(73) Assignee: ROHM CO., LTD., Kyoto-shi (JP)

(21) Appl. No.: 19/267,698

(22) Filed: Jul. 14, 2025

Related U.S. Application Data
(63) Continuation of application No. PCT/JP2024/000676, filed on Jan. 12, 2024.

(30) Foreign Application Priority Data
Jan. 16, 2023 (JP) 2023-004565
Jan. 9, 2024 (JP) 2024-001479

(51) Int. Cl. H10D 62/57; H10D 12/00; H10D 30/66; H10D 62/40; H10D 62/832; H10D 64/64

(52) U.S. Cl. CPC H10D 62/57; H10D 12/481; H10D 30/668; H10D 62/405; H10D 62/8325; H10D 64/647

(57) ABSTRACT

A semiconductor device includes an SiC chip that has a first principal surface and a second principal surface, an element structure that is formed in the first principal surface, and an electrode that is formed on the second principal surface and is electrically connected to the element structure and an arithmetic mean roughness (Ra) of the second principal surface is not less than 30 nm. An ohmic contact of low resistance can thereby be formed at the second principal surface at the opposite side to the element structure.

### CROSS-REFERENCE TO RELATED APPLICATIONS

The present application is a continuation application of PCT Application No. PCT/JP2024/000676, filed on Jan. 12, 2024, which corresponds to Japanese Patent Application No. 2023-004565 filed on Jan. 16, 2023 with the Japan Patent Office and Japanese Patent Application No. 2024-001479 filed on Jan. 9, 2024 with the Japan Patent Office, and the entire disclosures of these applications are incorporated herein by reference.

### TECHNICAL FIELD

The present disclosure relates to a semiconductor device.

### BACKGROUND ART

For example, Japanese Patent Application Publication No. 2022-166265 discloses an SiC semiconductor device including an SiC semiconductor layer that has a laminated structure including an SiC semiconductor substrate and an SiC epitaxial layer and having a first principal surface (element forming surface) formed by the SiC epitaxial layer and a side surface formed by the SiC semiconductor substrate and the SiC epitaxial layer and a modified line that is formed at the side surface in a portion constituted of the SiC semiconductor substrate at an interval from the SiC epitaxial layer and is modified to be of a property differing from the SiC semiconductor substrate.

### BRIEF DESCRIPTION OF THE DRAWINGS

FIG. 1 is a diagram showing a unit cell of a 4H-SiC monocrystal to which preferred embodiments of the present disclosure are applied.

FIG. 2 is a plan view showing a silicon plane of the unit cell of the 4H-SiC monocrystal of FIG. 1.

FIG. 3 is a schematic perspective view of a semiconductor device according to a first preferred embodiment of the present disclosure.

FIG. 4 is a schematic plan view of the semiconductor device of FIG. 3.

FIG. 5 is a sectional view taken along line V-V of FIG. 4.

FIG. 6 is an enlarged view of a region VI shown in FIG. 5.

FIG. 7 is a schematic plan view of a semiconductor device according to a second preferred embodiment of the present disclosure.

FIG. 8 is a sectional view taken along line VIII-VIII of FIG. 7.

FIG. 9 is a schematic sectional view of a semiconductor device according to a third preferred embodiment of the present disclosure.

FIG. 10 is a schematic sectional view of a semiconductor device according to a fourth preferred embodiment of the present disclosure.

FIG. 11 is a schematic sectional view of a semiconductor device according to a fifth preferred embodiment of the present disclosure.

FIG. 12 is a perspective view showing a semiconductor wafer used in manufacture of the semiconductor devices.

FIGS. 13A to 13E are diagrams showing a portion of a manufacturing process of the semiconductor devices.

FIG. 14 is a diagram showing a first shape (quadrangle shape) of laser marks formed in a rear surface of a chip.

FIG. 15 is a diagram showing a second shape (circular shape) of laser marks formed in the rear surface of the chip.

FIG. 16 is a photographic image showing the first shape (quadrangle shape) of laser marks formed in the rear surface of the chip.

FIG. 17 is a photographic image showing the second shape (circular shape) of laser marks formed in the rear surface of the chip.

FIG. 18 is a photographic image showing a modification example of the first shape (quadrangle shape) of laser marks formed in the rear surface of the chip.

FIG. 19 is a photographic image showing a modification example of the second shape (circular shape) of laser marks formed in the rear surface of the chip.

FIG. 20 is a diagram showing a third shape (quadrangle shape) of laser marks formed in the rear surface of the chip.

FIG. 21 is a diagram showing a fourth shape (quadrangle shape) of laser marks formed in the rear surface of the chip.

FIG. 22 is a diagram showing a fifth shape (circular shape) of laser marks formed in the rear surface of the chip.

FIG. 23 is a diagram showing a contact resistance distribution of a wafer rear surface and a state of the wafer rear surface according to Sample 1.

FIG. 24 is a diagram showing a contact resistance distribution of a wafer rear surface and a state of the wafer rear surface according to Sample 2.

### DESCRIPTION OF EMBODIMENTS

In the following, preferred embodiments of the present disclosure shall be described in detail with reference to the attached drawings.

### [Crystal Structure of SiC Monocrystal]

In each preferred embodiment of the present disclosure, an SiC (silicon carbide) monocrystal constituted of a hexagonal crystal is applied. The SiC monocrystal constituted of the hexagonal crystal has a plurality of polytypes including a 2H (hexagonal)-SiC monocrystal, a 4H-SiC monocrystal, a 6H-SiC monocrystal, etc., in accordance with period of atomic arrangement. Although, with each preferred embodiment of the present disclosure, an example where the 4H-SiC monocrystal is applied shall be described, this does not exclude other polytypes from the present disclosure.

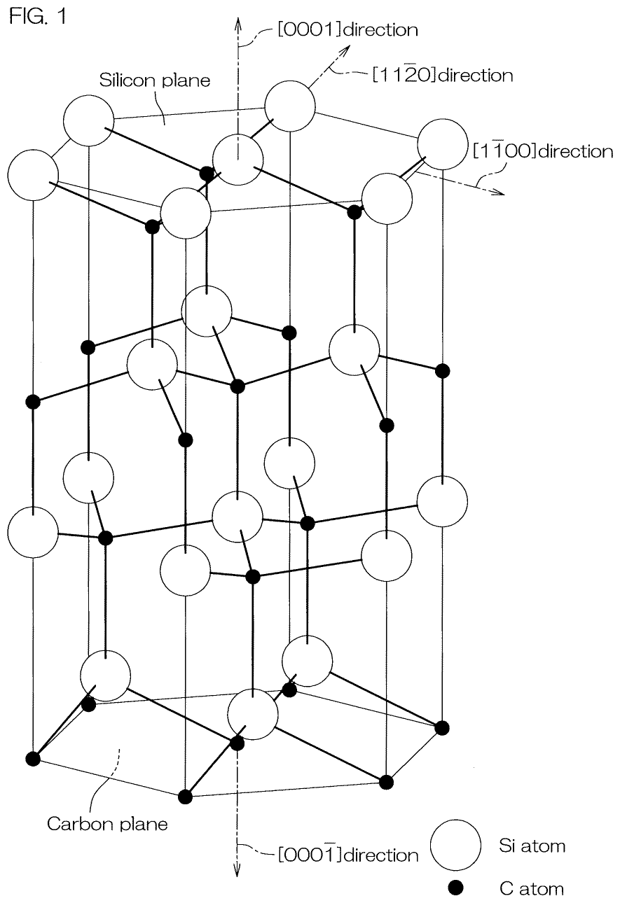

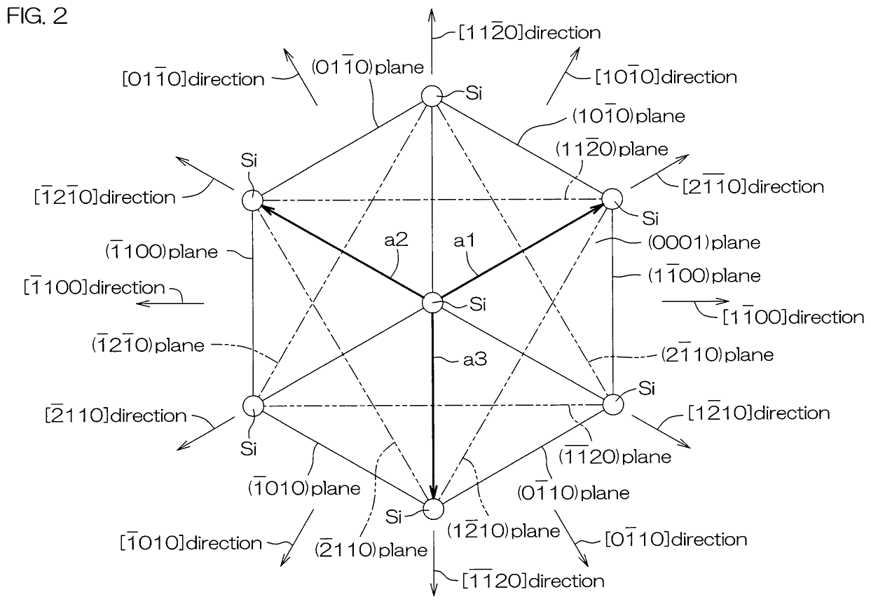

Hereinafter, a crystal structure of the 4H-SiC monocrystal shall be described. FIG. 1 is a diagram showing a unit cell of the 4H-SiC monocrystal (hereinafter, simply referred to as the “unit cell”) to which the preferred embodiments of the present disclosure are applied. FIG. 2 is a plan view showing a silicon plane of the unit cell of the 4H-SiC monocrystal of FIG. 1.

Referring to FIG. 1 and FIG. 2, the unit cell includes tetrahedral structures in each of which four C atoms are bonded to a single Si atom in a relationship of a tetrahedral arrangement (regular tetrahedral arrangement). The unit cell has an atomic arrangement in which the tetrahedral structures are stacked in a four-period. The unit cell has a hexagonal prism structure having a silicon plane of regular hexagonal shape, a carbon plane of regular hexagonal shape, and six side planes connecting the silicon plane and the carbon plane.

The silicon plane is an end plane terminated by Si atoms. At the silicon plane, a single Si atom is positioned at each of the six vertices of a regular hexagon and a single Si atom is positioned at a center of the regular hexagon.

The carbon plane is an end plane terminated by C atoms. At the carbon plane, a single C atom is positioned at each of the six vertices of a regular hexagon and a single C atom is positioned at a center of the regular hexagon.

Crystal planes of the unit cell are defined by four coordinate axes (a1, a2, a3, and c) including an a1-axis, an a2-axis, an a3-axis, and a c-axis. Of the four coordinate axes, a value of a3 takes on a value of −(a1+a2). The crystal planes of the 4H-SiC monocrystal shall be described below based on the silicon plane as an example of an end plane of the hexagonal crystal.

In a plan view of viewing the silicon plane from the c-axis, the a1-axis, the a2-axis, and the a3-axis are respectively set along directions of arrangement of the nearest neighboring Si atoms (hereinafter, simply referred to as the “nearest neighbor atom directions”) based on the Si atom positioned at the center. The a1-axis, the a2-axis, and the a3-axis are set to be shifted by 120° each in conformance to the arrangement of the Si atoms.

The c-axis is set in a normal direction to the silicon plane based on the Si atom positioned at the center. The silicon plane is a (0001) plane. The carbon plane is a (000-1) plane.

The side planes of the hexagonal prism include six crystal planes oriented along the nearest neighbor atom directions in the plan view of viewing the silicon plane from the c-axis. Specifically, the side planes of the hexagonal prism include the six crystal planes each having two nearest neighboring Si atoms in the plan view of viewing the silicon plane from the c-axis.

In the plan view of viewing the silicon plane from the c-axis, the side planes of the hexagonal prism include a (1-100) plane, a (0-110) plane, a (−1010) plane, a (−1100) plane, a (01-10) plane, and a (10-10) plane in clockwise order from a tip of the a1-axis.

Diagonal planes oriented along diagonal lines of the hexagonal prism include six crystal planes oriented along intersecting directions intersecting the nearest neighbor atom directions in the plan view of viewing the silicon plane from the c-axis. More specifically, the diagonal planes of the hexagonal prism include the six crystal planes each having two Si atoms that are not nearest neighbors in the plan view of viewing the silicon plane from the c-axis. When viewed on the basis of the Si atom positioned at the center, the directions intersecting the nearest neighbor atom directions are orthogonal directions orthogonal to the nearest neighbor atom directions.

In the plan view of viewing the silicon plane from the c-axis, the diagonal planes of the hexagonal prism include a (11-20) plane, a (1-210) plane, a (−2110) plane, a (−1-120) plane, a (−12-10) plane, and a (2-1-10) plane.

The crystal directions of the unit cell are defined by directions normal to the crystal planes. A normal direction to the (1-100) plane is a [1-100] direction. A normal direction to the (0-110) plane is a [0-110] direction. A normal direction to the (−1010) plane is a [−1010] direction. A normal direction to the (−1100) plane is a [−1100] direction. A normal direction to the (01-10) plane is a [01-10] direction. A normal direction to the (10-10) plane is a [10-10] direction.

A normal direction to the (11-20) plane is a [11-20] direction. A normal direction to the (1-210) plane is a [1-210] direction. A normal direction to the (−2110) plane is a [−2110] direction. A normal direction to the (−1-120) plane is a [−1-120] direction. A normal direction to the (−12-10) plane is a [−12-10] direction. A normal direction to the (2-1-10) plane is a [2-1-10] direction.

The hexagonal crystal is six-fold symmetrical and equivalent crystal planes and equivalent crystal directions are present at every 60°. For example, the (1-100) plane, the (0-110) plane, the (−1010) plane, the (−1100) plane, the (01-10) plane, and the (10-10) plane form equivalent crystal planes.

Also, the [1-100] direction, the [0-110] direction, the [−1010] direction, the [−1100] direction, the [01-10] direction, and the [10-10] direction form equivalent crystal directions. Also, the [11-20] direction, the [1-210] direction, the [−2110] direction, the [−1-120] direction, the [−12-10] direction, and the [2-1-10] direction form equivalent crystal directions.

The c-axis is in the [0001] direction ([000-1] direction). The a1-axis is in the [2-1-10] direction ([−2110] direction). The a2-axis is in the [−12-10] direction ([1-210] direction). The a3-axis is in the [−1-120] direction ([11-20] direction).

The (0001) plane and the (000-1) plane are collectively referred to as c-planes. The [0001] direction and the [000-1] direction are collectively referred to as c-axis directions. The (11-20) plane and the (−1-120) plane are collectively referred to as a-planes. The [11-20] direction and the [−1-120] direction are collectively referred to as a-axis directions. The (1-100) plane and the (−1100) plane are collectively referred to as m-planes. The [1-100] direction and the [−1100] direction are collectively referred to as m-axis directions.

### Semiconductor Device 1A According to First Preferred Embodiment

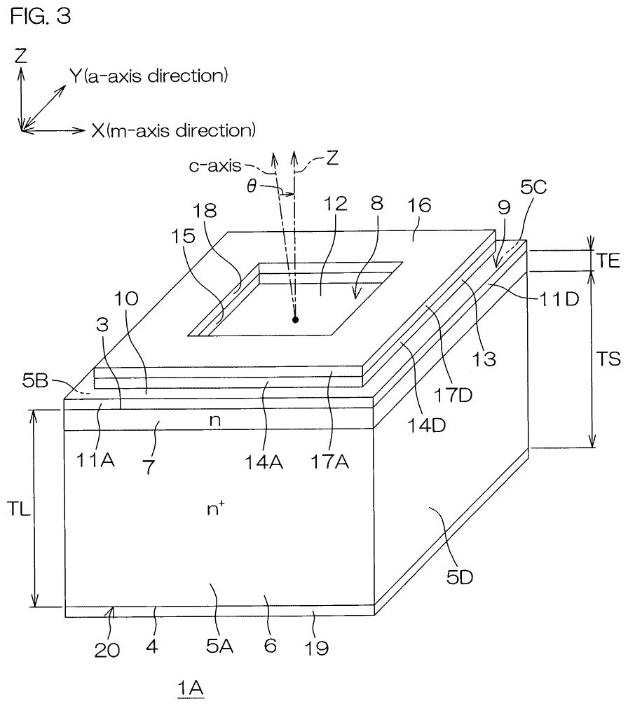

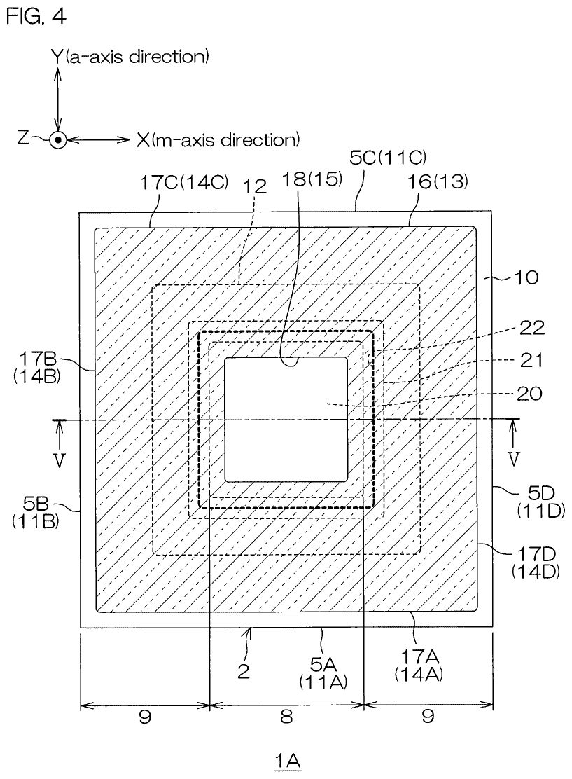

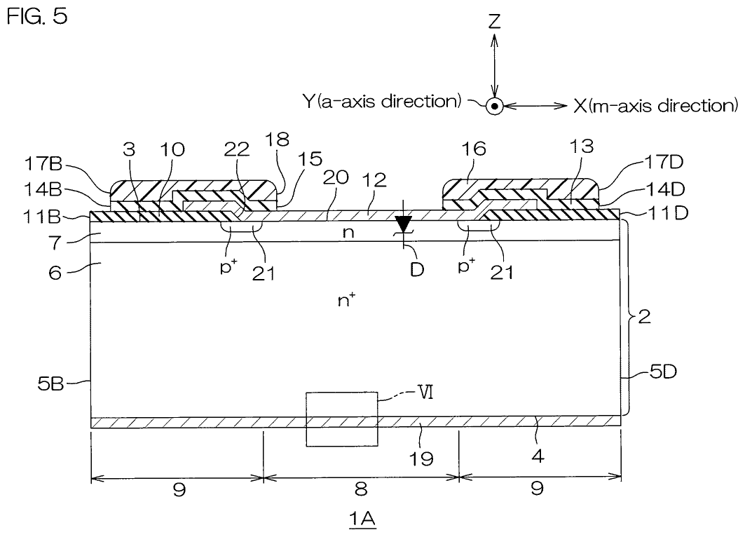

FIG. 3 is a schematic perspective view as viewed from one angle of a semiconductor device 1A according to a first preferred embodiment of the present disclosure. FIG. 4 is a plan view of the semiconductor device 1A shown in FIG. 3. FIG. 5 is a sectional view taken along line V-V shown in FIG. 4.

Referring to FIG. 3 to FIG. 5, the semiconductor device 1A is an SiC semiconductor device in this embodiment and includes an SiC semiconductor layer 2. The SiC semiconductor layer 2 includes a 4H-SiC monocrystal as an example of an SiC monocrystal constituted of a hexagonal crystal. The SiC semiconductor layer 2 is formed to a chip shape of rectangular parallelepiped shape.

The SiC semiconductor layer 2 has a first principal surface 3 at one side, a second principal surface 4 at another side, and side surfaces 5A, 5B, 5C, and 5D connecting the first principal surface 3 and the second principal surface 4. The first principal surface 3 and the second principal surface 4 are formed to a quadrangle shape (a square shape in this embodiment) in a plan view as viewed in a normal direction Z thereto (hereinafter simply referred to as “plan view”).

The first principal surface 3 is an element forming surface on which a semiconductor element is formed. The second principal surface 4 of the SiC semiconductor layer 2 is constituted of a ground surface having grinding marks. The side surfaces 5A to 5D are each constituted of a smooth cleavage surface arranged along a crystal plane of the SiC monocrystal. The side surfaces 5A to 5D do not have a grinding mark.

A thickness TL of the SiC semiconductor layer 2 may be not less than 50 μm and not more than 350 μm. The thickness TL may be not less than 80 μm and not more than 350 μm, not less than 100 μm and not more than 350 μm, not less than 150 μm and not more than 350 μm, not less than 50 μm and not more than 300 μm, not less than 80 μm and not more than 300 μm, not less than 100 μm and not more than 300 μm, not less than 150 μm and not more than 300 μm, not less than 50 μm and not more than 250 μm, not less than 80 μm and not more than 250 μm, not less than 100 μm and not more than 250 μm, or not less than 150 μm and not more than 250 μm. The thickness TL is preferably not less than 50 μm and not more than 350 μm and more preferably not less than 50 μm and not more than 300 μm. As long as the thickness TL is within the above ranges, a serial resistance of a Schottky barrier diode D can be reduced and thus an on resistance of the Schottky barrier diode D can be reduced.

In this embodiment, the first principal surface 3 and the second principal surface 4 are arranged along c-planes of the SiC monocrystal. The first principal surface 3 is arranged along the (0001) plane (silicon plane). The second principal surface 4 is arranged along the (000-1) plane (carbon plane) of the SiC monocrystal.

The first principal surface 3 and the second principal surface 4 have an off angle θ inclined at an angle of not more than 10° in the [11-20] direction with respect to the c planes of the SiC monocrystal. The normal direction Z is inclined by just the off angle θ with respect to the c-axis ([0001] direction) of the SiC monocrystal.

The off angle θ may be not less than 0° and not more than 5.0°. The off angle θ may be set in an angular range of not less than 0° and not more than 1.0°, not less than 1.0° and not more than 1.5°, not less than 1.5° and not more than 2.0°, not less than 2.0° and not more than 2.5°, not less than 2.5° and not more than 3.0°, not less than 3.0° and not more than 3.5°, not less than 3.5° and not more than 4.0°, not less than 4.0° and not more than 4.5°, or not less than 4.5° and not more than 5.0°. The off angle θ preferably exceeds 0°. The off angle θ may be less than 4.0°.

The off angle θ may be set in an angular range of not less than 3.0° and not more than 4.5°. In this case, the off angle θ is preferably set in an angular range of not less than 3.0° and not more than 3.5° or not less than 3.5° and not more than 4.0°.

The off angle θ may be set in an angular range of not less than 1.5° and not more than 3.0°. In this case, the off angle θ is preferably set in an angular range of not less than 1.5° and not more than 2.0° or not less than 2.0° and not more than 2.5°.

The first principal surface 3 is a device forming surface. The first principal surface 3 is a non-mounting surface. The second principal surface 4 is a mounting surface. When the semiconductor device 1A is mounted on a connection object, the SiC semiconductor layer 2 is mounted on the connection object in an orientation where the second principal surface 4 faces the object. An electronic component, a lead frame, a circuit board, etc., can be given as examples of the connection object.

The second principal surface 4 is constituted of a roughened surface that has been roughened. The second principal surface 4 is roughened by irregularly formed unevenness. Preferably, an entire area of the second principal surface 4 is roughened. The second principal surface 4 is especially preferably constituted of a roughened surface that does not have a grinding mark (more specifically, a grinding mark extending in a line shape). More specifically, the second principal surface 4 is a crystal surface constituted of an Si monocrystal. The second principal surface 4 is thus constituted of a crystalline roughened surface with which the Si monocrystal has been roughened.

An arithmetic mean roughness Ra of the second principal surface 4 may be not less than 30 nm. The arithmetic mean roughness Ra of the second principal surface 4 may be not less than 30 nm and not more than 1000 nm, not less than 50 nm and not more than 1000 nm, not less than 80 nm and not more than 1000 nm, not less than 100 nm and not more than 1000 nm, not less than 30 nm and not more than 800 nm, not less than 30 nm and not more than 600 nm, not less than 30 nm and not more than 400 nm, or not less than 30 nm and not more than 300 nm. The arithmetic mean roughness Ra of the second principal surface 4 is preferably not less than 30 nm and not more than 300 nm. When the arithmetic mean roughness Ra of the second principal surface 4 is not less than 30 nm and not more than 300 nm, an ohmic contact of low resistance can be achieved at the second principal surface 4 as shall be described below while preventing warping of a semiconductor wafer due to the surface roughness being excessive.

Lengths of the side surfaces 5A to 5D may each be not less than 0.5 mm and not more than 10 mm. Surface areas of the side surfaces 5A to 5D are equal to each other in this embodiment. When the first principal surface 3 and the second principal surface 4 are formed to a rectangular shape in plan view, the surface areas of the side surfaces 5A and 5C may be less than the surface areas of the side surfaces 5B and 5D or may exceed the surface areas of the side surfaces 5B and 5D.

In this embodiment, the side surface 5A and the side surface 5C extend in a first direction X and face each other in a second direction Y intersecting the first direction X. In this embodiment, the side surface 5B and the side surface 5D extend in the second direction Y and face each other in the first direction X. More specifically, the second direction Y is orthogonal to the first direction X.

In this embodiment, the first direction X is set to the m-axis direction ([1-100] direction) of the SiC monocrystal. The second direction Y is set to the a-axis direction ([11-20] direction) of the SiC monocrystal.

The side surface 5A and the side surface 5C are formed by the a-planes of the SiC monocrystal and face each other in the a-axis direction. The side surface 5A is formed by the (−1-120) plane of the SiC monocrystal. The side surface 5C is formed by the (11-20) plane of the SiC monocrystal.

The side surface 5B and the side surface 5D are formed by the m-planes of the SiC monocrystal and face each other in the m-axis direction. The side surface 5B is formed by the (−1100) plane of the SiC monocrystal. The side surface 5D is formed by the (1-100) plane of the SiC monocrystal.

The side surface 5A and the side surface 5C may form inclined surfaces that, when a normal to the first principal surface 3 of the SiC semiconductor layer 2 is taken as a basis, are inclined toward the c-axis direction ([0001] direction) of the SiC monocrystal with respect to the normal.

In this case, the side surface 5A and the side surface 5C may be inclined at an angle in accordance with the off angle θ with respect to the normal to the first principal surface 3 of the SiC semiconductor layer 2 when the normal to the first principal surface 3 of the SiC semiconductor layer 2 is 0°. The angle in accordance with the off angle θ may be equal to the off angle θ or may be an angle that exceeds 0° and is less than the off angle θ.

On the other hand, the side surface 5B and the side surface 5D extend as planes along the normal to the first principal surface 3 of the SiC semiconductor layer 2. More specifically, the side surface 5B and the side surface 5D are formed substantially perpendicular to the first principal surface 3 and the second principal surface 4.

In this embodiment, the SiC semiconductor layer 2 has a laminated structure that includes an SiC semiconductor substrate 6 of an n⁺-type and an SiC epitaxial layer 7 of an n-type. The second principal surface 4 of the SiC semiconductor layer 2 is formed by the SiC semiconductor substrate 6.

The first principal surface 3 of the SiC semiconductor layer 2 is formed by the SiC epitaxial layer 7. The side surfaces 5A to 5D of the SiC semiconductor layer 2 are formed by the SiC semiconductor substrate 6 and the SiC epitaxial layer 7.

An n-type impurity concentration of the SiC epitaxial layer 7 is not more than an n-type impurity concentration of the SiC semiconductor substrate 6. More specifically, the n-type impurity concentration of the SiC epitaxial layer 7 is less than the n-type impurity concentration of the SiC semiconductor substrate 6. The n-type impurity concentration of the SiC semiconductor substrate 6 may be not less than 1.0×10¹⁸ cm⁻³ and not more than 1.0×10²¹ cm⁻³. The n-type impurity concentration of the SiC epitaxial layer 7 may be not less than 1.0×10¹⁵ cm⁻³ and not more than 1.0×10¹⁸ cm⁻³.

A thickness TS of the SiC semiconductor substrate 6 may be not less than 40 μm and not more than 150 μm. The thickness TS may be not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, not less than 90 μm and not more than 100 μm, not less than 100 μm and not more than 110 μm, not less than 110 μm and not more than 120 μm, not less than 120 μm and not more than 130 μm, not less than 130 μm and not more than 140 μm, or not less than 140 μm and not more than 150 μm. The thickness TS is preferably not less than 40 μm and not more than 130 μm. By thinning the SiC semiconductor substrate 6, reduction of resistance value due to shortening of a current path can be achieved.

A thickness TE of the SiC epitaxial layer 7 may be not less than 1 μm and not more than 50 μm. The thickness TE may be not less than 1 μm and not more than 5 μm, not less than 5 μm and not more than 10 μm, not less than 10 μm and not more than 15 μm, not less than 15 μm and not more than 20 μm, not less than 20 μm and not more than 25 μm, not less than 25 μm and not more than 30 μm, not less than 30 μm and not more than 35 μm, not less than 35 μm and not more than 40 μm, not less than 40 μm and not more than 45 μm, or not less than 45 μm and not more than 50 μm. The thickness TE is preferably not less than 5 μm and not more than 15 μm.

An active region 8 and an outer region 9 are set in the SiC semiconductor layer 2. The active region 8 is a region in which the Schottky barrier diode D is formed as an example of an element structure. The outer region 9 is a region at an outer side of the active region 8.

In plan view, the active region 8 is set in a central portion of the SiC semiconductor layer 2 at intervals toward an inner region from the side surfaces 5A to 5D of the SiC semiconductor layer 2. In plan view, the active region 8 is set to a quadrangle shape having four sides parallel to the four side surfaces 5A to 5D of the SiC semiconductor layer 2.

The outer region 9 is set in a region between the side surfaces 5A to 5D of the SiC semiconductor layer 2 and peripheral edges of the active region 8. The outer region 9 is set to an endless shape (a quadrangle annular shape in this embodiment) surrounding the active region 8 in plan view.

A principal surface insulating layer 10 is formed on the first principal surface 3 of the SiC semiconductor layer 2. The principal surface insulating layer 10 selectively covers the active region 8 and the outer region 9. The principal surface insulating layer 10 may have a single layer structure constituted of a silicon oxide (SiO₂) layer or a silicon nitride (SiN) layer.

The principal surface insulating layer 10 may have a laminated structure that includes a silicon oxide layer and a silicon nitride layer. The silicon oxide layer may be formed on the silicon nitride layer. The silicon nitride layer may be formed on the silicon oxide layer. In this embodiment, the principal surface insulating layer 10 has a single layer structure constituted of the silicon oxide layer.

The principal surface insulating layer 10 has insulating side surfaces 11A, 11B, 11C, and 11D exposed from the side surfaces 5A to 5D of the SiC semiconductor layer 2. The insulating side surfaces 11A to 11D are continuous to the side surfaces 5A to 5D of the SiC semiconductor layer 2. The insulating side surfaces 11A to 11D are formed flush with respect to the side surfaces 5A to 5D. The insulating side surfaces 11A to 11D are constituted of cleavage surfaces.

A thickness of the principal surface insulating layer 10 may be not less than 1 μm and not more than 50 μm. The thickness of the principal surface insulating layer 10 may be not less than 1 μm and not more than 10 μm, not less than 10 μm and not more than 20 μm, not less than 20 μm and not more than 30 μm, not less than 30 μm and not more than 40 μm, or not less than 40 μm and not more than 50 μm.

A first principal surface electrode 12 is formed on the principal surface insulating layer 10. In plan view, the first principal surface electrode 12 is formed in the central portion of the SiC semiconductor layer 2 at intervals toward the inner region from the side surfaces 5A to 5D of the SiC semiconductor layer 2.

A passivation layer 13 (insulating layer) is formed on the principal surface insulating layer 10. The passivation layer 13 may have a single layer structure constituted of a silicon oxide layer or a silicon nitride layer.

The passivation layer 13 may have a laminated structure that includes a silicon oxide layer and a silicon nitride layer. The silicon oxide layer may be formed on the silicon nitride layer. The silicon nitride layer may be formed on the silicon oxide layer. In this embodiment, the passivation layer 13 has a single layer structure constituted of the silicon nitride layer.

In plan view, side surfaces 14A, 14B, 14C, and 14D of the passivation layer 13 are formed at intervals toward the inner region from the side surfaces 5A to 5D of the SiC semiconductor layer 2. In plan view, the passivation layer 13 exposes a peripheral edge portion of the first principal surface 3 of the SiC semiconductor layer 2. The passivation layer 13 exposes the principal surface insulating layer 10.

A sub pad opening 15 that exposes a portion of the first principal surface electrode 12 as a pad region is formed in the passivation layer 13. The sub pad opening 15 is formed to a quadrangle shape having four sides parallel to the side surfaces 5A to 5D of the SiC semiconductor layer 2 in plan view.

A thickness of the passivation layer 13 may be not less than 1 μm and not more than 50 μm. The thickness of the passivation layer 13 may be not less than 1 μm and not more than 10 μm, not less than 10 μm and not more than 20 μm, not less than 20 μm and not more than 30 μm, not less than 30 μm and not more than 40 μm, or not less than 40 μm and not more than 50 μm.

A resin layer 16 is formed on the passivation layer 13. The passivation layer 13 and the resin layer 16 form a single insulating laminated structure. In FIG. 4, the resin layer 16 is shown with hatching.

The resin layer 16 may contain a photosensitive resin of a negative type or a positive type. In this embodiment, the resin layer 16 contains a polybenzoxazole as an example of a photosensitive resin of the positive type. The resin layer 16 may instead contain a polyimide as an example of a photosensitive resin of the negative type.

In plan view, resin side surfaces 17A, 17B, 17C, and 17D of the resin layer 16 are formed at intervals toward the inner region from the side surfaces 5A to 5D of the SiC semiconductor layer 2. In plan view, the resin layer 16 exposes the peripheral edge portion of the first principal surface 3 of the SiC semiconductor layer 2. The resin layer 16, together with the passivation layer 13, exposes the principal surface insulating layer 10. In this embodiment, the resin side surfaces 17A to 17D of the resin layer 16 are formed flush with the side surfaces 14A to 14D of the passivation layer 13.

The resin side surfaces 17A to 17D of the resin layer 16 are portions that demarcated dicing streets when the semiconductor devices 1A to 1E are cut out from a single SiC semiconductor wafer. In this embodiment, the side surfaces 14A to 14D of the passivation layer 13 are also portions that demarcated the dicing streets.

By exposing the peripheral edge portion of the first principal surface 3 of the SiC semiconductor layer 2 from the resin layer 16 and the passivation layer 13, it is made unnecessary to physically cut the resin layer 16 and the passivation layer 13. The SiC semiconductor device 1A can thereby be cut out smoothly from the single SiC semiconductor wafer. Also, insulation distances from the side surfaces 5A to 5D of the SiC semiconductor layer 2 can be increased.

A distance between the side surfaces 5A to 5D and the resin side surfaces 17A to 17D (side surfaces 14A to 14D) may be not less than 1 μm and not more than 25 μm. The distance between the side surfaces 5A to 5D and the resin side surfaces 17A to 17D (side surfaces 14A to 14D) may be not less than 1 μm and not more than 5 μm, not less than 5 μm and not more than 10 μm, not less than 10 μm and not more than 15 μm, not less than 15 μm and not more than 20 μm, or not less than 20 μm and not more than 25 μm. As a matter of course, the side surfaces 14A to 14D of the passivation layer 13 may be formed flush with respect to the side surfaces 5A to 5D of the SiC semiconductor layer 2.

A pad opening 18 that exposes the portion of the first principal surface electrode 12 as the pad region is formed in the resin layer 16. The pad opening 18 is formed to a quadrangle shape having four sides parallel to the side surfaces 5A to 5D of the SiC semiconductor layer 2 in plan view. The pad opening 18 is formed to a quadrangle shape having four sides parallel to the side surfaces 5A to 5D of the SiC semiconductor layer 2 in plan view.

The pad opening 18 is in communication with the sub pad opening 15. Inner walls of the pad opening 18 are formed flush with inner walls of the sub pad opening 15. The inner walls of the pad opening 18 may be positioned toward the side surface 5A to 5D sides of the SiC semiconductor layer 2 with respect to the inner walls of the sub pad opening 15. The inner walls of the pad opening 18 may be positioned toward the inner region of the SiC semiconductor layer 2 with respect to the inner walls of the sub pad opening 15. The resin layer 16 may cover the inner walls of the sub pad opening 15.

A thickness of the resin layer 16 may be not less than 1 μm and not more than 50 μm. The thickness of the resin layer 16 may be not less than 1 μm and not more than 10 μm, not less than m and not more than 20 μm, not less than 20 μm and not more than 30 μm, not less than 30 μm and not more than 40 μm, or not less than 40 μm and not more than 50 μm.

A second principal surface electrode 19 is formed on the second principal surface 4 of the SiC semiconductor layer 2. The second principal surface electrode 19 forms an ohmic contact with the second principal surface 4 (SiC semiconductor substrate 6) of the SiC semiconductor layer 2.

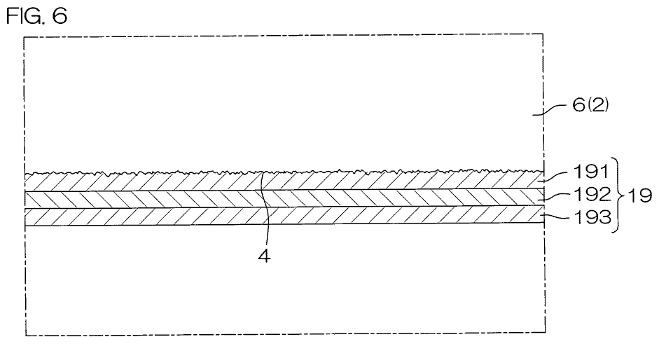

Referring to FIG. 6, the second principal surface electrode 19 has a laminated structure that includes a plurality of electrode layers laminated on the second principal surface 4. In this embodiment, the second principal surface electrode 19 has the laminated structure that includes a metal layer 191, a first electrode layer 192, and a second electrode layer 193 laminated in that order from the second principal surface 4 side.

The metal layer 191 is directly connected to the roughened second principal surface 4. The metal layer 191 preferably covers an entire area of the second principal surface 4. In this embodiment, the metal layer 191 is a base layer of the first electrode layer 192 and the second electrode layer 193 and may be referred to as a “metal base layer.”

From a standpoint of material, the metal layer 191 may be a silicide layer in this embodiment. The metal layer 191 is a nickel silicide layer (NiSi, NiSi₂, etc.), a titanium silicide layer (TiSi, TiSi₂, Ti₅Si₃, etc.), a tungsten silicide layer (WSi₂), a molybdenum silicide layer (MoSi₂), a tantalum silicide layer (TaSi₂), a cobalt silicide layer (CoSi₂), or a platinum silicide layer (PtSi₂). Among the above, the metal layer 191 is preferably a nickel silicide layer or a titanium silicide layer and more preferably a nickel silicide layer.

The first electrode layer 192 is sandwiched between the metal layer 191 and the second electrode layer 193. The first electrode layer 192 preferably covers an entire area of the metal layer 191. The first electrode layer 192 contains the same type of metal as the metal layer 191. In this embodiment, the first electrode layer 192 is an Ni layer.

The second electrode layer 193 is the electrode layer that is outermost of the second principal surface electrode 19 and is the layer that is directly connected to the connection object of the semiconductor device 1A. The second electrode layer 193 may be referred to as an outermost electrode layer. The second electrode layer 193 preferably covers an entire area of the first electrode layer 192. In this embodiment, the second electrode layer 193 is an Au layer.

Referring to FIG. 5, a diode region 20 of the n-type is formed in a surface layer portion of the first principal surface 3 of the SiC semiconductor layer 2 in the active region 8. In this embodiment, the diode region 20 is formed in a central portion of the first principal surface 3 of the SiC semiconductor layer 2. In this embodiment, the diode region 20 is set to a quadrangle shape having four sides parallel to the side surfaces 5A to 5D of the SiC semiconductor layer 2 in plan view.

An n-type impurity concentration of the diode region 20 may be not less than the n-type impurity concentration of the SiC epitaxial layer 7. In this embodiment, the diode region 20 is formed using a portion of the SiC epitaxial layer 7. The n-type impurity concentration of the diode region 20 is equal to the n-type impurity concentration of the SiC epitaxial layer 7. The diode region 20 may be formed by introduction of an n-type impurity into a surface layer portion of the SiC epitaxial layer 7.

A p⁺-type guard region 21 is formed in a surface layer portion of the first principal surface 3 of the SiC semiconductor layer 2 in the outer region 9. The guard region 21 is formed as a band extending along the diode region 20 in plan view.

More specifically, the guard region 21 is formed to an endless shape (for example, a quadrangle annular shape, a quadrangle annular shape with chamfered corners, or a circular annular shape) surrounding the diode region 20 in plan view. The guard region 21 is thereby formed as a guard ring region. In this embodiment, the diode region 20 is defined by the guard region 21. Also, the active region 8 is defined by the guard region 21.

A p-type impurity of the guard region 21 does not have to be activated. In this case, the guard region 21 is formed as a non-semiconductor region. The p-type impurity of the guard region 21 may be activated. In this case, the guard region 21 is formed as a p-type semiconductor region.

The principal surface insulating layer 10 described above is formed on the first principal surface 3 of the SiC semiconductor layer 2. A diode opening 22 that exposes the diode region 20 is formed in the principal surface insulating layer 10. The diode opening 22 exposes an inner peripheral edge of the guard region 21 in addition to the diode region 20. The diode opening 22 is formed to a quadrangle shape having four sides parallel to the side surfaces 5A to 5D of the SiC semiconductor layer 2 in plan view.

The first principal surface electrode 12 described above is formed on the principal surface insulating layer 10. The first principal surface electrode 12 enters into the diode opening 22 from above the insulating layer. Inside the diode opening 22, the first principal surface electrode 12 is electrically connected to the diode region 20. The first principal surface electrode 12 is not limited in particular as long as it is a metal that forms a Schottky junction by junction with SiC of the n-type and, for example, titanium (Ti), molybdenum (Mo), palladium (Pd), platinum (Pt), etc., can be used.

More specifically, the first principal surface electrode 12 forms a Schottky junction with the diode region 20. The Schottky barrier diode D, having the first principal surface electrode 12 as an anode and the diode region 20 as a cathode, is thereby formed. The passivation layer 13 and the resin layer 16 described above are formed on the principal surface insulating layer 10.

### Semiconductor Device 1B According to Second Preferred Embodiment

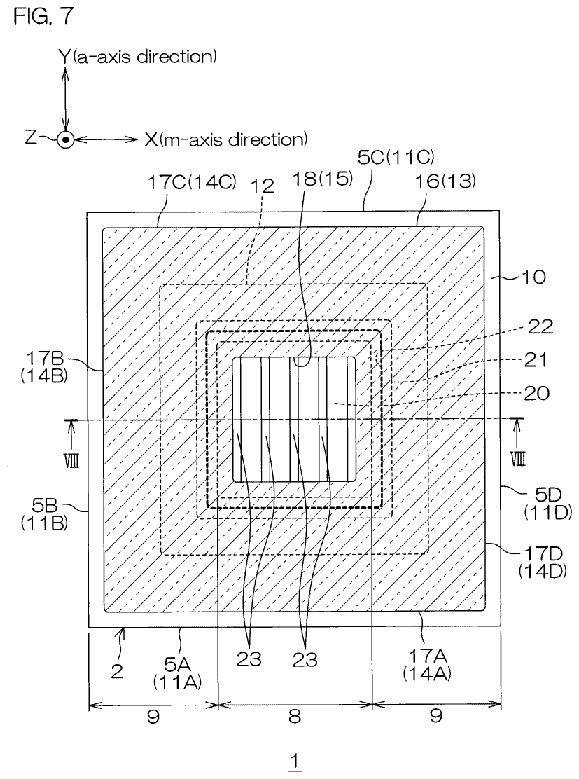

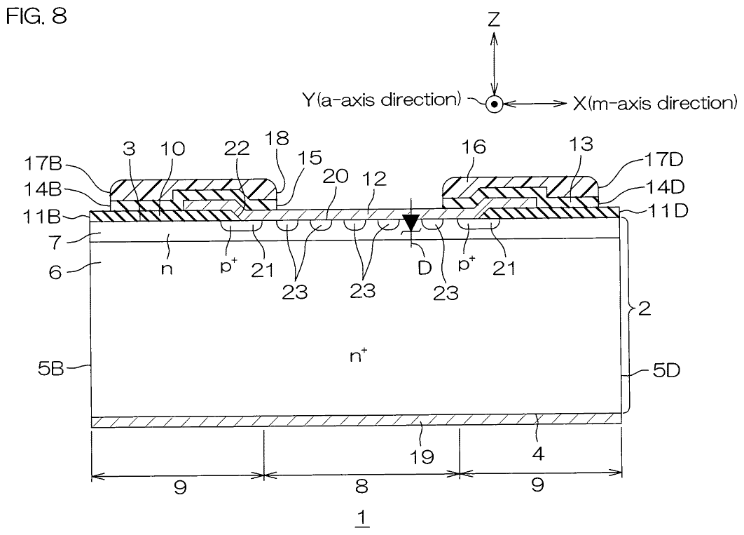

FIG. 7 is a schematic plan view of a semiconductor device 1B according to a second preferred embodiment of the present disclosure. FIG. 8 is a sectional view taken along line VIII-VIII of FIG. 7. In the following, structures corresponding to structures described with the preferred embodiment described above shall be provided with the same reference signs and description thereof shall be omitted.

With the semiconductor device 1B, a plurality of JBS (junction barrier Schottky) structures 23 of a p⁺-type are formed in a surface layer portion of the first principal surface 3 of the diode region 20. In this embodiment, the plurality of JBS structures 23 are formed in stripes extending along the diode region 20 in plan view. The plurality of JBS structures 23 are formed by a plurality of semiconductor regions of the p⁺-type being disposed discretely in the diode region 20. Besides being arranged in stripes, the plurality of JBS structures 23 may be arranged in an array or a staggered arrangement in the diode region 20.

### Semiconductor Device 1C According to Third Preferred Embodiment

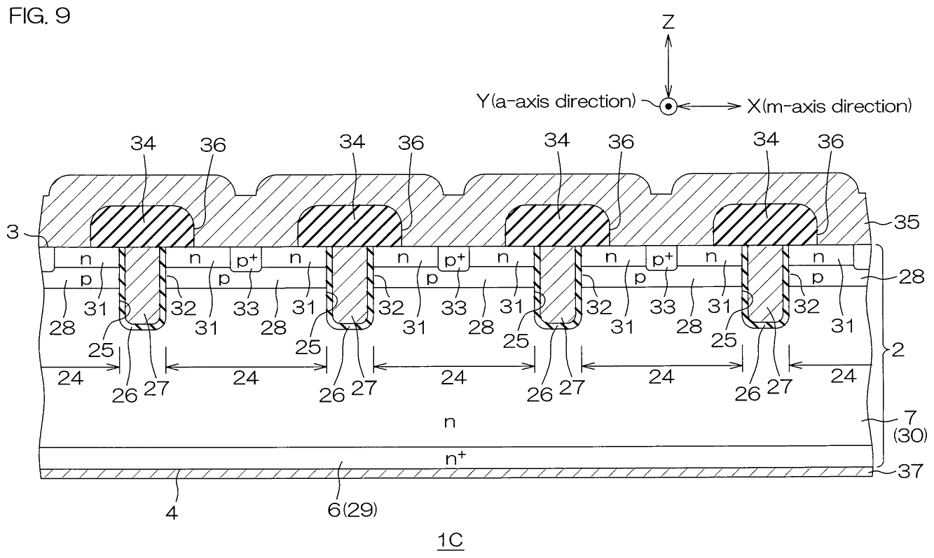

FIG. 9 is a schematic sectional view of a semiconductor device 1C according to a third preferred embodiment of the present disclosure. In the following, structures corresponding to structures described with the preferred embodiments described above shall be provided with the same reference signs and description thereof shall be omitted.

The semiconductor device 1C includes a MOSFET of a trench gate structure as an example of an element structure. Gate trenches 25 that demarcate a plurality of unit cells 24 are formed in a surface layer portion of the first principal surface 3 of the SiC epitaxial layer 7. The plurality of gate trenches 25 may be formed in stripes extending along the a-axis direction.

A bottom portion of each gate trench 25 is positioned at a thickness direction intermediate portion of the SiC epitaxial layer 7. An edge portion at which a side surface and the bottom portion of each gate trench 25 intersect is formed in a shape that is curved toward an outer side of each gate trench 25 and each gate trench 25 is formed in a U-shape in sectional view. When the edge portion of each gate trench 25 is curved, an electric field that concentrates at the edge portion can be relaxed.

In each gate trench 25, a gate electrode 27 is embedded with a gate insulating film 26 interposed therebetween. The gate electrode 27 has a front surface that is flush with the first principal surface 3 of the SiC epitaxial layer 7. The gate insulating film 26 may be constituted, for example, of a silicon oxide film, a silicon nitride film, a silicon oxynitride film, a hafnium oxide film, an alumina film, a tantalum oxide film, etc. Also, the gate electrode 27 may be constituted, for example, of a polysilicon that has been made low in resistance by implantation of an impurity. A body region 28 of the p-type that constitutes the unit cell 24 is formed in each region between mutually adjacent gate trenches 25.

In regard to a thickness direction of the SiC epitaxial layer 7, a bottom portion of the body region 28 is positioned between the first principal surface 3 of the SiC epitaxial layer 7 and the bottom portion of the gate trench 25. In a lateral direction along the first principal surface 3 of the SiC epitaxial layer 7, an end portion of the body region 28 forms a portion of the gate trench 25. That is, the body region 28 faces the gate electrode 27 across the gate insulating film 26.

In this embodiment, the SiC semiconductor substrate 6 is a drain region 29 of the n⁺-type and a region between the body region 28 and the drain region 29 is a drift region 30 of an n⁻ type.

A source region 31 of the n-type is formed in an inner region of the body region 28. In regard to the thickness direction of the SiC epitaxial layer 7, the source region 31 is formed shallower than the body region 28. In the lateral direction along the first principal surface 3 of the SiC epitaxial layer 7, an end portion of the source region 31 forms a portion of the gate trench 25. That is, the source region 31 faces the gate electrode 27 across the gate insulating film 26.

In regard to the thickness direction of the SiC epitaxial layer 7, a region along the side surface of the gate trench 25 between a lower end of the source region 31 and a lower end of the body region 28 is a channel region 32 of the p-type. A body contact region 33 of the p⁺-type is formed such as to penetrate through the source region 31.

The body contact region 33 is formed such as to penetrate through the source region 31 and cross a boundary between the source region 31 and the body region 28. The body contact region 33 has a higher impurity concentration than the body region 28.

An interlayer insulating film 34 that covers the gate electrode 27 is formed on the SiC epitaxial layer 7. Contact holes 36 that selectively expose portions of the source region 31 and the body contact regions 33 are formed in the interlayer insulating film 34. A source electrode 35 is formed on the interlayer insulating film 34. The source electrode 35 may include, for example, at least one type among a pure Al layer (an Al layer with a purity of not less than 99%), a pure Cu layer (a Cu layer with a purity of not less than 99%), an AlCu alloy layer, an AlSiCu alloy layer and an AlSi alloy layer.

Inside each contact hole 36, the source electrode 35 forms an ohmic contact with the body region 28, a portion of the source region 31, and the body contact region 33. On the other hand, a drain electrode 37 is formed on the second principal surface 4 of the SiC semiconductor substrate 6. The drain electrode 37 forms an ohmic contact with the drain electrode 29. The drain electrode 37 is formed of the same material as the second principal surface electrode 19 described above. That is, the drain electrode 37 has the laminated structure that includes the metal layer 191, the first electrode layer 192, and the second electrode layer 193 shown in FIG. 6.

### Semiconductor Device 1D According to Fourth Preferred Embodiment

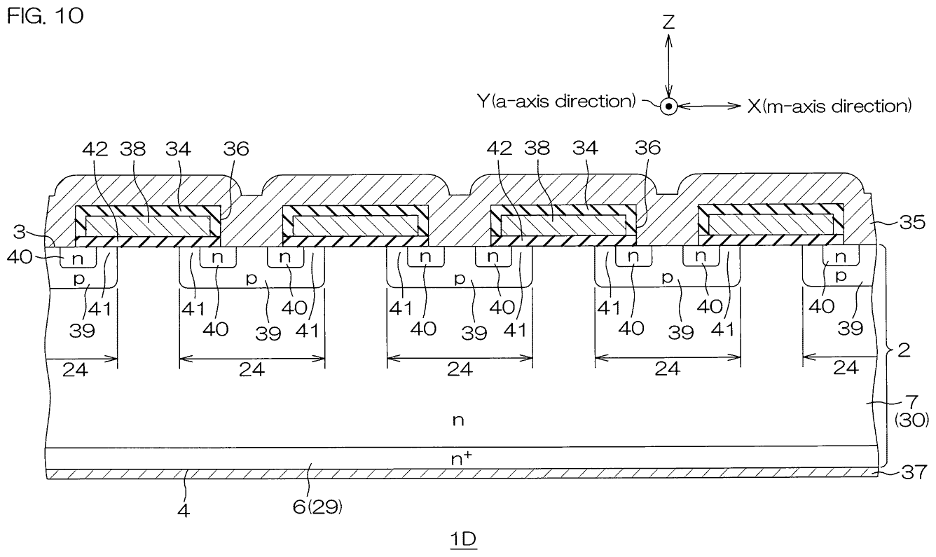

FIG. 10 is a schematic sectional view of a semiconductor device 1D according to a fourth preferred embodiment of the present disclosure. In the following, structures corresponding to structures described with the preferred embodiments described above shall be provided with the same reference signs and description thereof shall be omitted.

A point in which the semiconductor device 1D differs from the semiconductor device 1C described above is the point that a planar gate structure in which gate electrodes 38 are formed along the first principal surface 3 is formed in place of the gate electrodes 27. That is, the semiconductor device 1D includes a MOSFET of the planar gate structure as an example of an element structure.

Body regions 39 are formed at intervals on the SiC epitaxial layer 7 and source regions 40 are formed in inner regions thereof. Each source region 40 is formed at a position at an interval from a peripheral edge portion of the body region 39. With the semiconductor device 1D, the body regions 39 of the p-type and the source regions 40 of the n-type are doubly diffused in surface layer portions of the SiC epitaxial layer 7 (drift region 30). A region between a peripheral edge portion of each source region 40 and a peripheral edge portion of each body region 39 is a channel region 41.

The plurality of gate electrodes 38 that face the channel regions 41 with gate insulating films 42 interposed therebetween are formed on the SiC epitaxial layer 7. Materials of the gate insulating films 42 and the gate electrodes 38 are the same as in the semiconductor device 1C described above.

Each gate electrode 38 faces a region that extends across the SiC epitaxial layer 7 outside body regions 39, the body regions 39, and source regions 40. Also, the gate electrode 38 includes overlap portions that protrude to the source region 40 sides from boundary lines between the source regions 40 and the body regions 39.

### Semiconductor Device 1E According to Fifth Preferred Embodiment

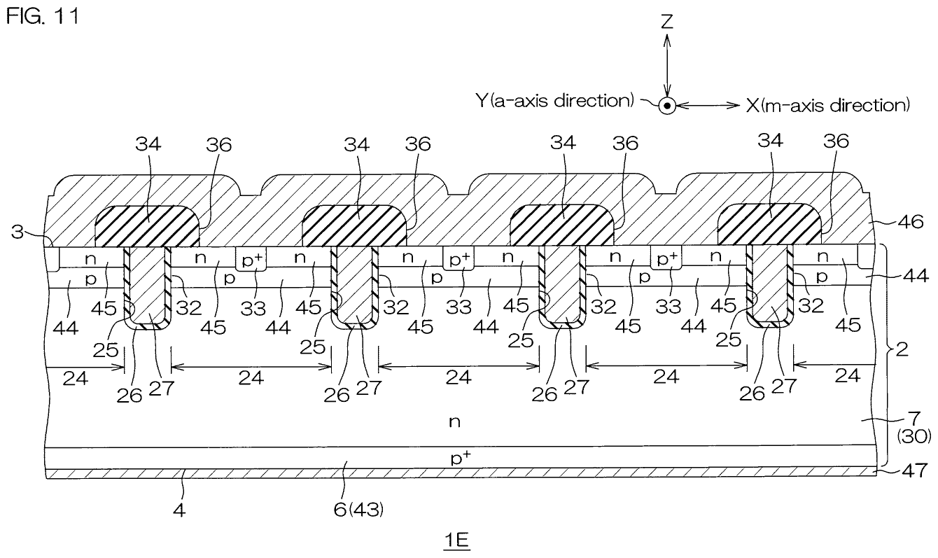

FIG. 11 is a schematic sectional view of a semiconductor device 1E according to a fifth preferred embodiment of the present disclosure. In the following, structures corresponding to structures described with the preferred embodiments described above shall be provided with the same reference signs and description thereof shall be omitted.

A point in which the semiconductor device 1E differs from the semiconductor device 1C described above is the point that the semiconductor device 1E includes an IGBT (insulated gate bipolar transistor) as an example of an element structure by the drain region 29 being replaced by a collector region 43 of the p⁺-type. The body region 28, the source region 31, the source electrode 35, and the drain electrode 37 may each be a base region 44 of the p-type, an emitter region 45 of the n-type, an emitter electrode 46, and a collector electrode 47, respectively.

### [Method for Manufacturing Semiconductor Devices 1A to 1E]

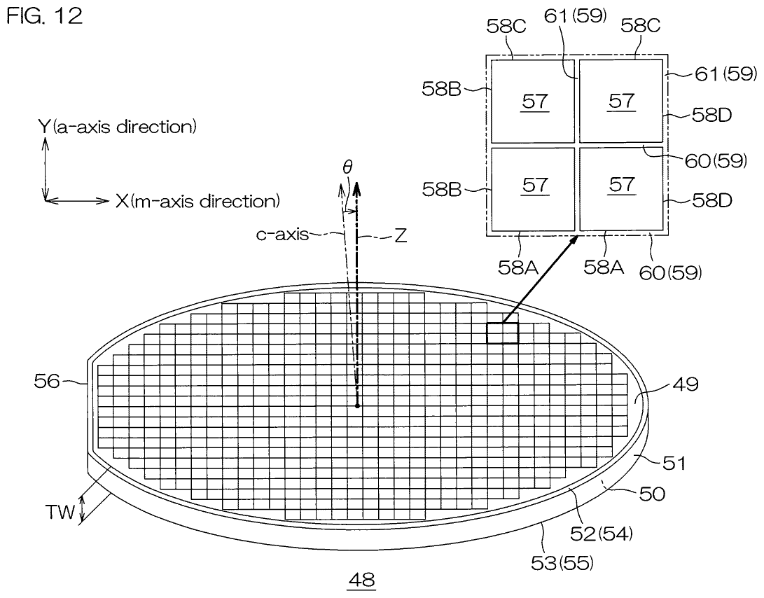

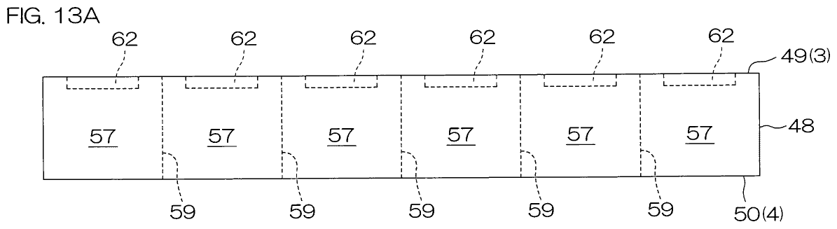

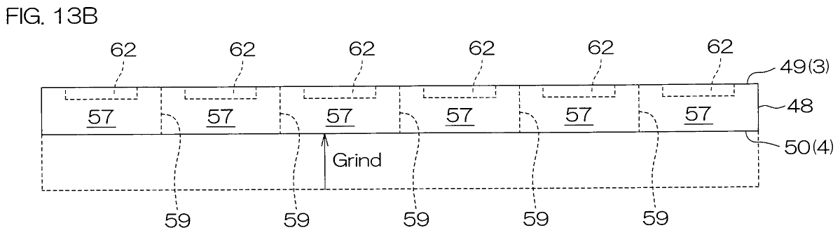

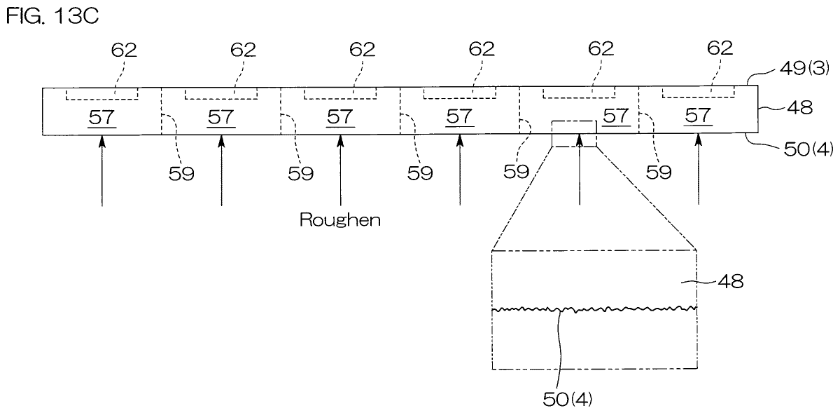

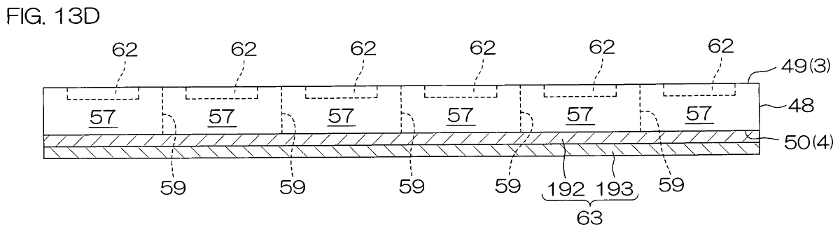

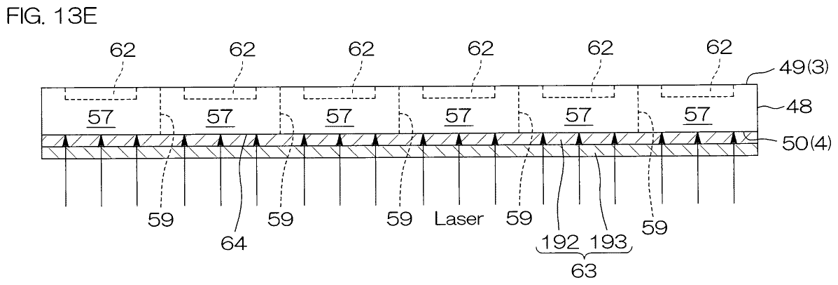

FIG. 12 is a perspective view showing an SiC semiconductor wafer 48 used in manufacture of the semiconductor devices 1A to 1E. FIG. 13A to FIG. 13D are diagrams each showing a portion of a manufacturing process of the semiconductor devices 1A to 1E in order of process.

The SiC semiconductor wafer 48 is a member that is to be abase of the SiC semiconductor substrate 6. The SiC semiconductor wafer 48 includes a 4H-SiC monocrystal as an example of an SiC monocrystal constituted of a hexagonal crystal. In this embodiment, the SiC semiconductor wafer 48 has an n-type impurity concentration corresponding to the n-type impurity concentration of the SiC semiconductor substrate 6.

The SiC semiconductor wafer 48 is formed to a plate shape or discoid shape. The SiC semiconductor wafer 48 may be formed to a disk shape instead. The SiC semiconductor wafer 48 has a first wafer principal surface 49 at one side, a second wafer principal surface 50 at another side, and a wafer side surface 51 connecting the first wafer principal surface 49 and the second wafer principal surface 50.

A thickness TW of the SiC semiconductor wafer 48 exceeds the thickness TS of the SiC semiconductor substrate 6 (see FIG. 3) (TS<TW). The thickness TW of the SiC semiconductor wafer 48 is adjusted by grinding to the thickness TS of the SiC semiconductor substrate 6.

The thickness TW may exceed 150 μm and be not more than 750 μm. The thickness TW may exceed 150 μm and be not more than 300 μm, be not less than 300 μm and not more than 450 μm, be not less than 450 μm and not more than 600 μm, or be not less than 600 μm and not more than 750 μm. In view of grinding time of the SiC semiconductor wafer 48, the thickness TW preferably exceeds 150 μm and is not more than 500 μm. The thickness TW is typically not less than 300 μm and not more than 450 μm.

In this embodiment, the first wafer principal surface 49 and the second wafer principal surface 50 are arranged along c-planes of the SiC monocrystal. The first wafer principal surface 49 is arranged along the (0001) plane (silicon plane). The second wafer principal surface 50 is arranged along the (000-1) plane (carbon plane) of the SiC monocrystal.

The first wafer principal surface 49 and the second wafer principal surface 50 have an off angle θ inclined at an angle of not more than 10° in the [11-20] direction with respect to the c-planes of the SiC monocrystal. A normal direction Z to the first wafer principal surface 49 is inclined by just the off angle θ with respect to the c-axis ([0001] direction) of the SiC monocrystal.

The off angle θ may be not less than 0° and not more than 5.0°. The off angle θ may be set in an angular range of not less than 0° and not more than 1.0°, not less than 1.0° and not more than 1.5°, not less than 1.5° and not more than 2.0°, not less than 2.0° and not more than 2.5°, not less than 2.5° and not more than 3.0°, not less than 3.0° and not more than 3.5°, not less than 3.5° and not more than 4.0°, not less than 4.0° and not more than 4.5°, or not less than 4.5° and not more than 5.0°. The off angle θ preferably exceeds 0°. The off angle θ may be less than 4.0°.

The off angle θ may be set in an angular range of not less than 3.0° and not more than 4.5°. In this case, the off angle θ is preferably set in an angular range of not less than 3.0° and not more than 3.5° or not less than 3.5° and not more than 4.0°.

The off angle θ may be set in an angular range of not less than 1.5° and not more than 3.0°. In this case, the off angle θ is preferably set in an angular range of not less than 1.5° and not more than 2.0° or not less than 2.0° and not more than 2.5°.

The SiC semiconductor wafer 48 includes a first wafer corner portion 52 connecting the first wafer principal surface 49 and the wafer side surface 51 and a second wafer corner portion 53 connecting the second wafer principal surface 50 and the wafer side surface 51. The first wafer corner portion 52 has a first chamfered portion 54 that is inclined downwardly from the first wafer principal surface 49 toward the wafer side surface 51. The second wafer corner portion 53 has a second chamfered portion 55 that is inclined downwardly from the second wafer principal surface 50 toward the wafer side surface 51.

The first chamfered portion 54 may be formed to a convexly curved shape. The second chamfered portion 55 may be formed to a convexly curved shape. The first chamfered portion 54 and the second chamfered portion 55 suppress cracking of the SiC semiconductor wafer 48.

A single orientation flat 56, as an example of a marker indicating a crystal orientation of the SiC monocrystal, is formed in the wafer side surface 51 of the SiC semiconductor wafer 48. The orientation flat 56 is a notched portion formed in the wafer side surface 51 of the SiC semiconductor wafer 48. In this embodiment, the orientation flat 56 extends rectilinearly along the a-axis direction ([11-20] direction) of the SiC monocrystal.

A plurality of (for example, two) orientation flats 56 indicating the crystal orientation may be formed in the wafer side surface 51 of the SiC semiconductor wafer 48. The plurality of (for example, two) orientation flats 56 may include a first orientation flat and a second orientation flat.

The first orientation flat may be a notched portion extending rectilinearly along the a-axis direction ([11-20] direction) of the SiC monocrystal. The second orientation flat may be a notched portion extending rectilinearly along the m-axis direction ([1-100] direction) of the SiC monocrystal.

A plurality of the device forming regions 57 respectively corresponding to the SiC semiconductor devices 1A to 1E are set in the first wafer principal surface 49 of the SiC semiconductor wafer 48. The plurality of device forming regions 57 are set in an array of matrix form at intervals in the m-axis direction ([1-100] direction) and the a-axis direction ([11-20] direction).

Each device forming region 57 has four sides 58A, 58B, 58C, and 58D oriented along the crystal orientation of the SiC monocrystal. The four sides 58A to 58D respectively correspond to the four side surfaces 5A to 5D of the SiC semiconductor layer 2. That is, the four sides 58A to 58D include the two sides 58A and 58C oriented along the m-axis direction ([1-100] direction) and the two sides 58B and 58D oriented along the a-axis direction ([11-20] direction).

The plurality of device forming regions 57 are respectively demarcated by scheduled cutting lines 59 of lattice shape extending along the m-axis direction ([1-100] direction) and the a-axis direction ([11-20] direction). The scheduled cutting lines 59 include a plurality of first scheduled cutting lines 60 and a plurality of second scheduled cutting lines 61.

The plurality of first scheduled cutting lines 60 respectively extend along the m-axis direction ([1-100] direction). The plurality of second scheduled cutting lines 61 respectively extend along the a-axis direction ([11-20] direction).

Referring to FIG. 13A, in the manufacturing process of the semiconductor devices 1A to 1E, predetermined element structures 62 (the Schottky barrier diode D and the respective unit cells 24, etc., of the MOSFET of the trench gate structure, the MOSFET of the planar gate structure, and the IGBT of the trench gate structure described above) are fabricated in the plurality of device forming regions 57.

Next, referring to FIG. 13B, the second wafer principal surface 50 of the SiC semiconductor wafer 48 is ground. The second wafer principal surface 50 of the SiC semiconductor wafer 48 may be ground by a CMP (chemical mechanical polishing method). The SiC semiconductor wafer 48 is thereby thinned to a desired thickness.

Next, referring to FIG. 13C, the second wafer principal surface 50 of the SiC semiconductor wafer 48 is roughened. The second wafer principal surface 50 is preferably roughened by an etching method. The second wafer principal surface 50 may be roughened until it is of an arithmetic mean roughness Ra of not less than 30 nm. The second wafer principal surface 50 is preferably roughened until the arithmetic mean roughness Ra becomes not less than 30 nm and not more than 300 nm.

Next, referring to FIG. 13D, a rear surface electrode 63 is formed at once across an entire area of the roughened second wafer principal surface 50. The rear surface electrode 63 includes the second principal surface electrode 19 (see FIG. 5 and FIG. 8), the drain electrode 37 (see FIG. 9 and FIG. 10), and the collector electrode 47 (see FIG. 11) described above. With the rear surface electrode 63, for example, electrode materials of the first electrode layer 192 and the second electrode layer 193 are laminated successively by a sputter method.

Next, referring to FIG. 13E, a contact portion of the first electrode layer 192 is laser annealed by irradiation of a laser on a boundary surface 64 between the first electrode layer 192 and the second wafer principal surface 50. Thereby, the material of the first electrode layer 192 (in this embodiment, Ni) and the Si of the SiC semiconductor wafer 48 react and the metal layer 191 (see FIG. 6) is formed between the first electrode layer 192 and the SiC semiconductor wafer 48.

In the laser annealing treatment, the laser is irradiated continuously across the entire area of the second wafer principal surface 50 such that ranges of an irradiation unit processable by a single shot of laser irradiation overlap with each other. The irradiation range of the single laser shot differs according to a pulse energy of the single laser short. For example, the greater the pulse energy, the more necessary it is to focus the energy in a narrow range and therefore, the narrower the irradiation range of the single shot.

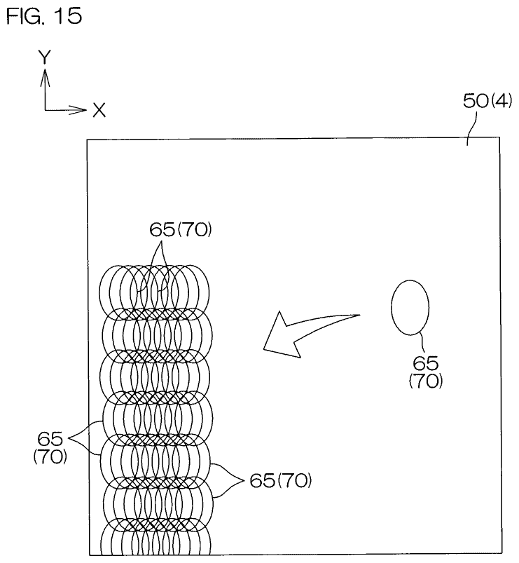

The irradiation range of the single shot differs according to the laser irradiation apparatus and, for example, referring to FIG. 15, when the pulse energy of the single shot is a first energy of not less than 3.0 J/cm², the irradiation range of the single shot may be a small circular shape 65. A size of the circular shape 65 may, for example, be not less than 10 μm diameter (10 μm ϕ) and not more than 100 μm diameter (100 μm ϕ). As shown in FIG. 15, the laser is irradiated such that several circular shapes 65 overlap with each other.

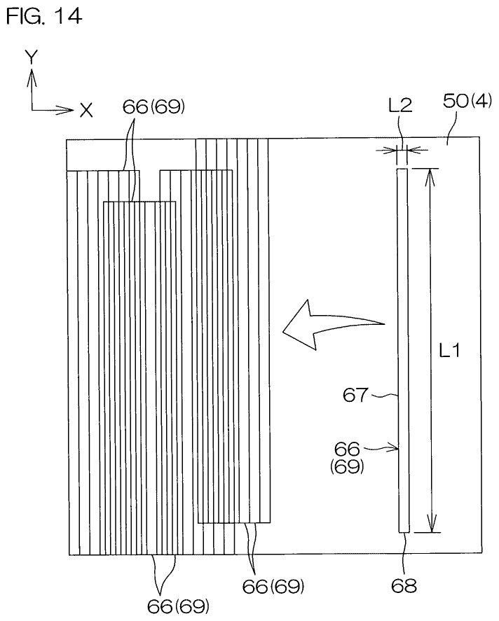

On the other hand, referring to FIG. 14, when the pulse energy of the single shot is a second energy less than the first energy, the irradiation range of the single shot may be a quadrangle shape 66 having a wider area than the circular shape 65. In regard to a size of the quadrangle shape 66, for example, the quadrangle shape 66 may be a rectangle and, for example, a length L1 of a long side 67 in an arbitrary second direction Y may be not less than 5 times a length L2 of a short side 68 in a first direction X orthogonal to the second direction Y. More specifically, the length L2 of the short side 68 may be not less than 0.1 mm and not more than 0.4 mm and the length L1 of the long side 67 may be not less than 1.0 mm and not more than 4.0 mm. Here, in regard to the first direction X and the second direction Y, mutually orthogonal directions are merely defined for convenience as the first direction X and the second direction Y. The first direction X may be referred to as a “sheet surface lateral direction” or a “second direction” and the second direction Y may be referred to as a “sheet surface longitudinal direction” or a “first direction.”

The shapes of the single laser shots shown in FIG. 14 and FIG. 15 remain as laser marks (processing marks) on the second wafer principal surface 50 after the laser annealing treatment. The laser marks can be checked, for example, by observing the second principal surface 4 upon removing the rear surface electrode 63 (the second principal surface electrode 19, the drain electrode 37, or the collector electrode 47, etc.) of any of the semiconductor devices 1A to 1E after completion. In the case of FIG. 14, a plurality of processing units 69 formed in quadrangle shape in plan view remain by overlapping mutually on the second principal surface 4 (second wafer principal surface 50). In the case of FIG. 15, a plurality of processing units 70 formed in circular shape in plan view remain by overlapping mutually on the second principal surface 4 (second wafer principal surface 50).

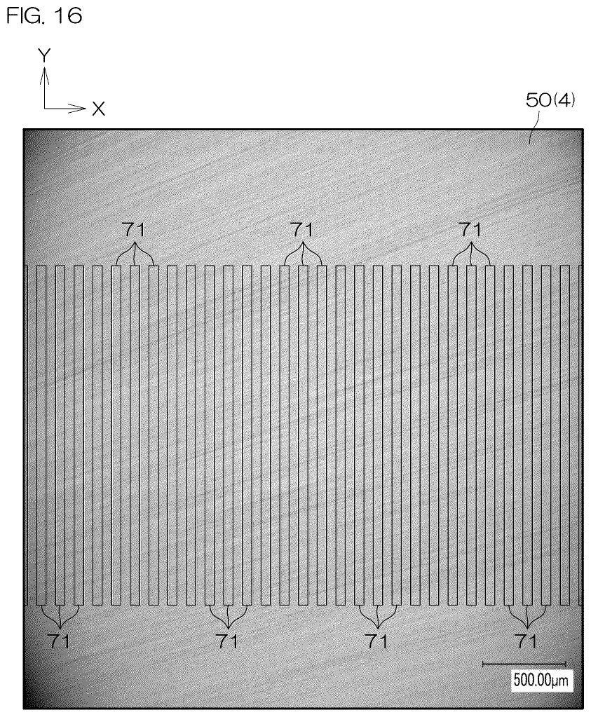

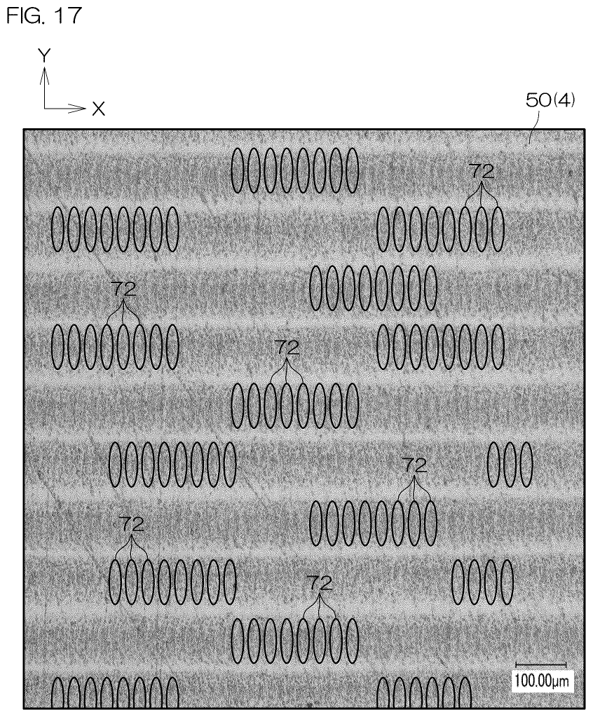

FIG. 16 is a photographic image showing the first shape (quadrangle shape) of laser marks 71 formed in the second principal surface 4 (second wafer principal surface 50). FIG. 17 is a photographic image showing the second shape (circular shape) of laser marks 72 formed in the second principal surface 4 (second wafer principal surface 50). That is, FIG. 16 and FIG. 17 are respectively, photographic images showing the laser marks 71 and 72 formed by overlap of the processing units 69 and 70 of FIG. 14 and FIG. 15.

Referring to FIG. 16, with laser irradiation by a relatively low pulse energy (for example, of not more than 2.0 J/cm²), the plurality of laser marks 71 of band shape that are blackish and are thinly elongate along the second direction Y of the second wafer principal surface 50 are formed. The plurality of laser marks 71 are arranged regularly along the first direction X. Particularly in FIG. 16, the plurality of laser marks 71 of band shape are aligned at substantially equal intervals along the first direction X.

Referring to FIG. 17, with laser irradiation by a relatively high pulse energy (for example, of not less than 3.0 J/cm²), the plurality of laser marks 72 of elliptical shape that are blackish and have a major axis along the second direction Y of the second wafer principal surface 50 are formed. The plurality of laser marks 72 are arranged regularly along the first direction X. Particularly in FIG. 17, the plurality of laser marks 72 of elliptical shape are aligned at substantially equal intervals along the first direction X.

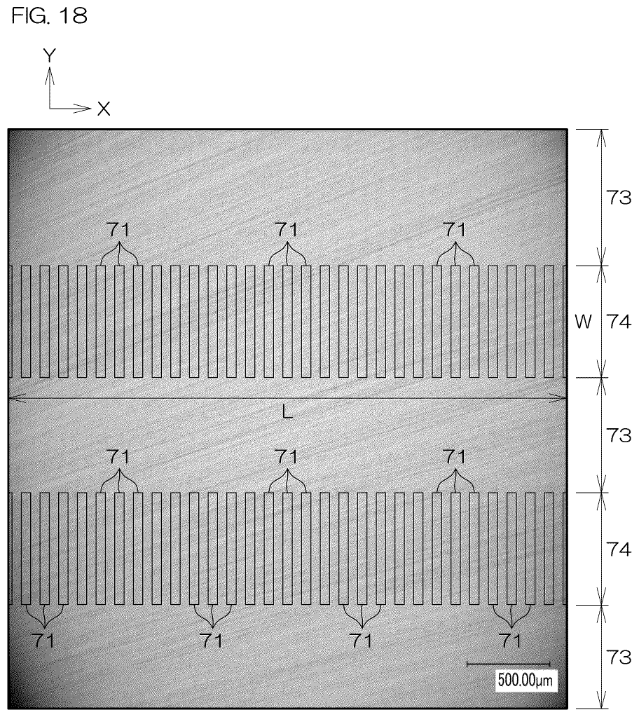

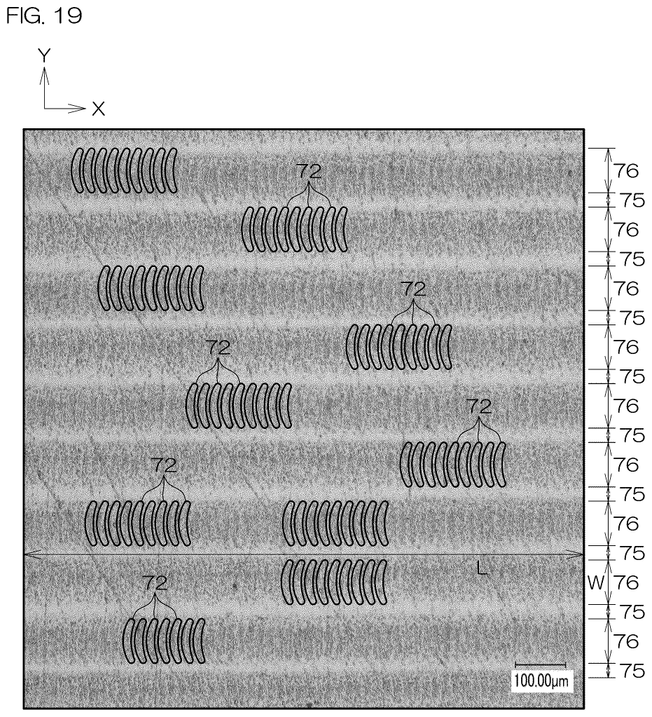

FIG. 18 is a photographic image showing a modification example of the laser marks 71. FIG. 19 is a photographic image showing a modification example of the laser marks 72.

Referring to FIG. 18, the laser marks 71 may be of a band shape shorter than the laser marks 71 shown in FIG. 16. The plurality of laser marks 71 may be formed selectively on the second principal surface 4 (second wafer principal surface 50) and a region of band shape extending along the first direction X may be formed. The region of band shape may be a dark region 74 formed by arrangement of the plurality of laser marks 71 that are blackish. The dark region 74 is a region of darker hue than a base region 73 of the second principal surface 4 (second wafer principal surface 50). In this embodiment, the base regions 73 and the dark regions 74 are arranged alternately along the second direction Y. Also, an aspect ratio (W/L) of a length (L) in the first direction X and a width (W) in the second direction Y of each dark region 74 may be not more than 0.1.

Referring to FIG. 19, the laser marks 72 may be of a curved line shape that is long along the second direction Y (to put in another way, a bow shape that is long along the second direction Y). The plurality of laser marks 72 may be formed selectively on the second principal surface 4 (second wafer principal surface 50) and a region of band shape extending along the first direction X may be formed. The region of band shape may be a dark region 76 formed by arrangement of the plurality of laser marks 72 that are blackish. The dark region 76 is a region of darker hue than a base region 75 of the second principal surface 4 (second wafer principal surface 50). In this embodiment, the base regions 75 and the dark regions 76 are arranged alternately along the second direction Y. Also, an aspect ratio (W/L) of a length (L) in the first direction X and a width (W) in the second direction Y of each dark region 76 may be not more than 0.1.

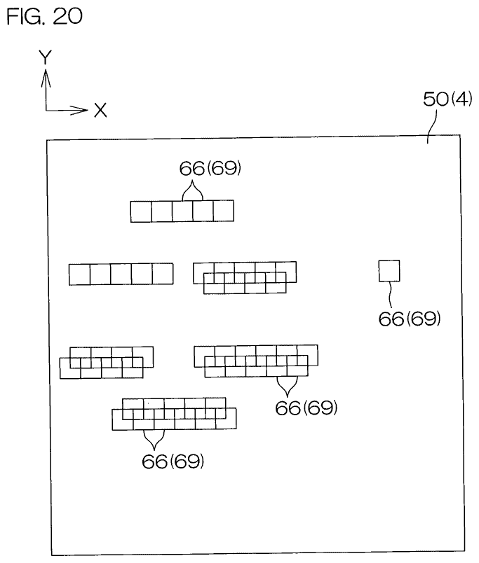

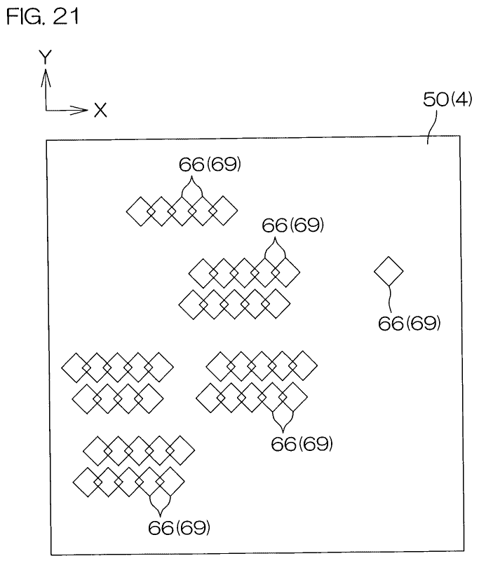

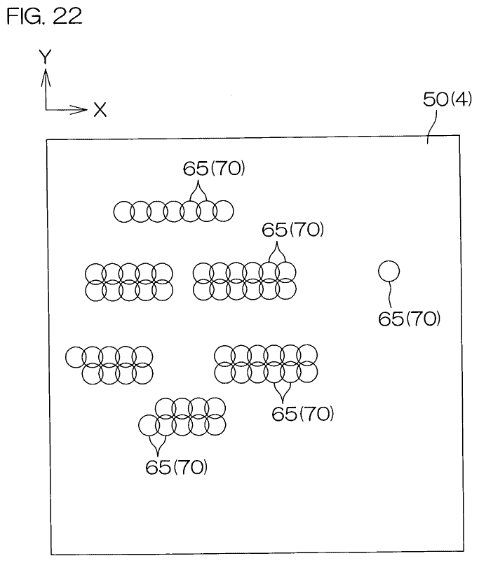

Also, whereas the processing units 69 of FIG. 14 are of rectangular shape, the processing units 69 of square shape shown in FIG. 20 or the processing units 69 of rhomboid shape shown in FIG. 21 may also be adopted as the processing units 69 of quadrangle shape. Also, whereas the processing units 70 of FIG. 15 are of elliptical shape, the processing units 70 of perfect circular shape shown in FIG. 22 may also be adopted as the processing units 70 of circular shape.

Thereafter, the plurality of semiconductor devices 1A to 1E are cut out by cutting the SiC semiconductor wafer 48 along the scheduled cutting lines 59.

### [Effect Due to Roughening of the Second Principal Surface 4]

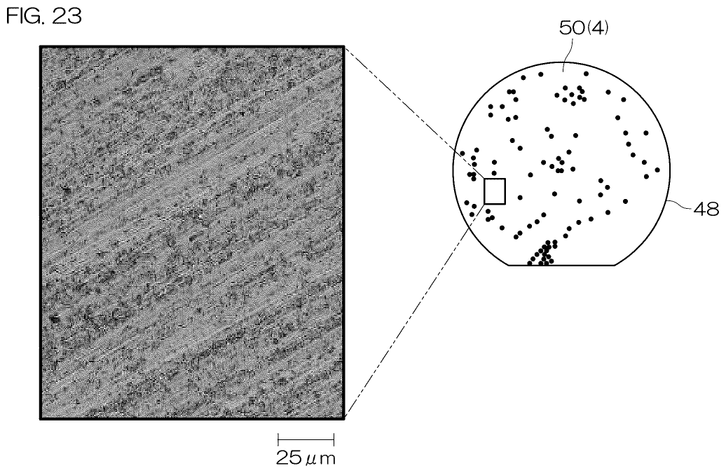

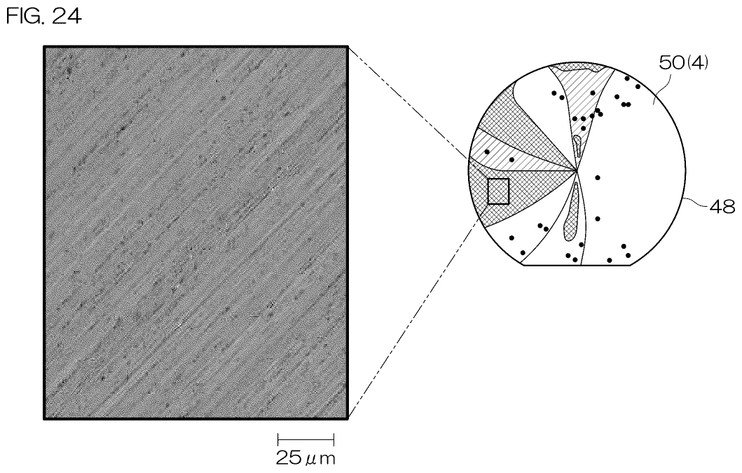

As described above, with the semiconductor devices 1A to 1E, the second principal surface 4 of the SiC semiconductor layer 2 is roughened such that the arithmetic mean roughness Ra is not less than 30 nm. Thereby, an ohmic contact of low resistance can be formed between the rear surface electrode 63 (the second principal surface electrode 19, the drain electrode 37, or the collector electrode 47, etc.) and the second principal surface 4 even with laser annealing treatment by a comparatively low energy. This effect can be confirmed, for example, by comparison of Sample 1 and Sample 2 with reference to FIG. 23 and FIG. 24.

With Sample 1 and Sample 2, besides the arithmetic mean roughness Ra of the second wafer principal surface 50 (second principal surface 4) being different, the rear surface electrode 63 was formed under the same conditions on the second wafer principal surface 50. With both samples, the energy of the single laser shot when annealing the rear surface electrode 63 was not more than 2.0 J/cm².

FIG. 23 is a diagram showing a contact resistance distribution of the second wafer principal surface 50 of the SiC semiconductor wafer 48 and a state of the second wafer principal surface 50 according to Sample 1. FIG. 24 is a diagram showing a contact resistance distribution of the second wafer principal surface 50 of the SiC semiconductor wafer 48 and a state of the second wafer principal surface 50 according to Sample 2.

With the SiC semiconductor wafer 48 at the right side of the sheet of FIG. 23, black dots indicate portions of higher contact resistance than the other white regions. The photographic image at the left side of the sheet of FIG. 23 shows the surface state of the second wafer principal surface 50. FIG. 23 shows the surface state of the second wafer principal surface 50 when the arithmetic mean roughness Ra of the second wafer principal surface 50 is 60 μm.

With the SiC semiconductor wafer 48 at the right side of the sheet of FIG. 24, black dots, cross-hatched regions, and obliquely hatched regions indicate portions of higher contact resistance than the other white regions. The resistance of the cross-hatched regions is especially high. The photographic image at the left side of the sheet of FIG. 24 shows the surface state of the second wafer principal surface 50. FIG. 24 shows the surface state of the second wafer principal surface 50 when the arithmetic mean roughness Ra of the second wafer principal surface 50 is 15 μm.

Comparing FIG. 23 and FIG. 24, it was found that even with the laser annealing treatment by the low energy of not more than 2.0 J/cm², an ohmic contact of low resistance can be formed between the rear surface electrode 63 and the second principal surface 4 with Sample 1 with which roughening is performed to the Ra of not less than 30 μm. In regard to this attainment of low resistance, increase in contact area between the second principal surface 4 and the rear surface electrode 63 by roughening of the second principal surface 4 is included as a factor.

Since the ohmic contact of low resistance can thus be obtained by the laser annealing treatment by the low energy of not more than 2.0 J/cm², the irradiation area per single laser shot can be made large as shown in FIG. 14. For example, the processing units 69 that are larger than the processing units 70 shown in FIG. 15 can be realized. Consequently, the laser annealing treatment can be performed efficiently and therefore, manufacturing efficiency of the semiconductor devices 1A to 1E can be improved.

Also, with Sample 1, since the Ra is approximately 60 μm, warping hardly occurred in the SiC semiconductor wafer 48 and problems did not occur in handling in transfer during forming and after forming of the rear surface electrode 63. Although warping of the SiC semiconductor wafer 48 can be reduced effectively when the second principal surface 4 is flattened as in Sample 2 of FIG. 24, it is oppositely difficult to obtain an ohmic contact of low resistance unless the laser annealing treatment is performed with a high energy. That is, with Sample 1, prevention of warping of the SiC semiconductor wafer 48 and reduction of the ohmic contact of low resistance at the second principal surface 4 can be achieved at the same time in a well-balanced manner.

The reduction of resistance of the ohmic contact at the second wafer principal surface 50 (second principal surface 4) such as the above is effective for the semiconductor devices 1A to 1E that include the comparatively thin SiC semiconductor layer 2 of not less than 50 μm and not more than 350 μm. In a case of a vertical type device in which a current is made to flow in a thickness direction of the SiC semiconductor layer 2, a serial resistance in the thickness direction of the SiC semiconductor layer 2 is small when the thickness TL of the SiC semiconductor layer 2 is thin. An influence of the resistance of the ohmic contact at the second wafer principal surface 50 (second principal surface 4) on the serial resistance is therefore large, the reduction of resistance of the ohmic contact at the second wafer principal surface 50 (second principal surface 4) such as the above is effective.

Especially with a Schottky barrier diode such as the semiconductor devices 1A and 1B, the element structure at the first principal surface 3 side is simple and there are only a few elements that would become a factor of increase in serial resistance. The influence of the resistance of the ohmic contact at the second wafer principal surface 50 (second principal surface 4) on the serial resistance is therefore large in comparison to a MOSFET, etc., with which the element structure is complex, and thus the reduction of resistance of the ohmic contact at the second wafer principal surface 50 (second principal surface 4) such as the above is even more effective.

Although the preferred embodiments of the present disclosure were described above, the present disclosure can be implemented in yet other embodiments.

For example, with each of the preferred embodiments described above, a structure with which the conductivity types of the respective semiconductor portions are inverted may be adopted. For example, portions of the p-type may be changed to be of the n-type and portions of the n-type may be changed to be of the p-type.

The preferred embodiments of the present disclosure described above are exemplary in all aspects and should not be interpreted restrictively and it is intended that changes are included in all aspects.

The following appended features can be extracted from the descriptions in this Description and the drawings.

### APPENDIX 1-1

A semiconductor device (1A to 1E) including
an SiC chip (2) that has a first principal surface (3) and a second principal surface (4),
an element structure (D, 24) that is formed in the first principal surface (3), and
an electrode (19, 37, 47) that is formed on the second principal surface (4), is electrically connected to the element structure (D, 24), and includes a metal layer (191) bonded to the second principal surface (4), and
where an arithmetic mean roughness (Ra) of the second principal surface (4) is not less than 30 nm and
laser marks formed by mutual overlapping of a plurality of processing units (69, 70) each formed in a quadrangle shape or a circular shape in plan view are formed in the second principal surface (4).

With this arrangement, since the arithmetic mean roughness (Ra) of the second principal surface (4) of the SiC chip (2) is not less than 30 nm, a contact area of the SiC chip (2) and the electrode (19, 37, 47) can be made large. Consequently, the semiconductor device (1A to 1E) with which it is possible to form an ohmic contact of low resistance at the second principal surface (4) at the opposite side to the element structure (D, 24) can be provided.

### APPENDIX 1-2

The semiconductor device (1A to 1E) according to Appendix 1-1, where a thickness (TL) of the SiC chip (2) is not less than 50 μm and not more than 350 μm.

### APPENDIX 1-3

The semiconductor device (1A to 1E) according to Appendix 1-2, where the thickness (TL) of the SiC chip (2) is not less than 100 μm and not more than 350 μm.

### APPENDIX 1-4

The semiconductor device (1A to 1E) according to any one of Appendix 1-1 to Appendix 1-3, where the Ra of the second principal surface (4) is not more than 100 nm.

### APPENDIX 1-5

The semiconductor device (1A to 1E) according to any one of Appendix 1-1 to Appendix 1-4, where each of the processing units (69, 70) is formed, in plan view, to a rectangular shape including a short side (68) and a long side (67) and
a length (L1) of the long side (67) is not less than five times a length (L2) of the short side (68).

### APPENDIX 1-6

The semiconductor device (1A to 1E) according to Appendix 1-5, where the length (L2) of the short side (68) of each of the processing units (69, 70) is not less than 0.1 mm and not more than 0.4 mm and the length (L1) of the long side (67) of each of the processing units (69, 70) is not less than 1.0 mm and not more than 4.0 mm.

### APPENDIX 1-7

The semiconductor device (1A to 1E) according to any one of Appendix 1-1 to Appendix 1-6, where the metal layer (191) is a silicide layer (191).

### APPENDIX 1-8

The semiconductor device (1A to 1E) according to Appendix 1-7, where the silicide layer (191) is a nickel silicide layer (191) and
the electrode (19, 37, 47) is formed of a metal that includes Ni.

### APPENDIX 1-9

The semiconductor device (1A to 1E) according to any one of Appendix 1-1 to Appendix 1-8, where the first principal surface (3) is a silicon plane and the second principal surface (4) is a carbon plane.

### APPENDIX 1-10

The semiconductor device (1A, 1B) according to any one of Appendix 1-1 to Appendix 1-9, where the element structure (D) includes a Schottky barrier diode (D) that is formed in the first principal surface (3) and has a Schottky metal (19) that forms a Schottky junction with the first principal surface (3).

### APPENDIX 1-11

The semiconductor device (1B) according to Appendix 1-10, where the SiC chip (2) includes a first semiconductor region (7) of a first conductivity type that is formed in a surface layer portion of the first principal surface (3) and a JBS (junction barrier Schottky) structure (23) that is formed by a plurality of semiconductor regions of a second conductivity type selectively formed in a forming region (20) of the Schottky junction in the first principal surface (3).

### APPENDIX 1-12

The semiconductor device (1C, 1E) according to any one of Appendix 1-1 to Appendix 1-9, where the SiC chip (2) includes a first semiconductor region (7, 30) of a first conductivity type that is formed in a surface layer portion of the first principal surface (3) and
the element structure (24) includes a gate trench (25) that is formed in the first principal surface (3), a gate electrode (27) that is embedded in the gate trench (25) with a gate insulating film (26) interposed therebetween, and a second semiconductor region (31, 45) of the first conductivity type and a third semiconductor region (28, 44) of a second conductivity type that are formed successively in a depth direction of the gate trench (25) from the first principal surface (3).

### APPENDIX 1-13

The semiconductor device (1C) according to Appendix 1-12, where the SiC chip (2) includes a drain region (29) of the first conductivity type that is formed in a surface layer portion of the second principal surface (4) and
the second semiconductor region is a source region (31).

### APPENDIX 1-14

The semiconductor device (1E) according to Appendix 1-12, where the SiC chip (2) includes a collector region (43) of the second conductivity type that is formed in a surface layer portion of the second principal surface (4) and
the second semiconductor region is an emitter region (45).

### APPENDIX 1-15

The semiconductor device (1D) according to any one of Appendix 1-1 to Appendix 1-9, where the SiC chip (2) includes a first semiconductor region (7, 30) of a first conductivity type that is formed in a surface layer portion of the first principal surface (3) and the element structure (24) includes a body region (39) of a second conductivity type and a source region (40) of the first conductivity type in an interior of the body region (39) that are doubly diffused in a surface layer portion of the first semiconductor region (7, 30) and a gate electrode (38) that is formed on the first principal surface (3) with a gate insulating film (42) interposed therebetween and faces a channel region (41) between an outer edge of the body region (39) and an outer edge of the source region (40).

### APPENDIX 2-1

A semiconductor device (1A to 1E) including
an SiC chip (2) that has a first principal surface (3) and a second principal surface (4),
an element structure (D, 24) that is formed in the first principal surface (3), and
an electrode (19, 37, 47) that is formed on the second principal surface (4), is electrically connected to the element structure (D, 24), and includes a metal layer (191) bonded to the second principal surface (4), and
where an arithmetic mean roughness (Ra) of the second principal surface (4) is not less than 30 nm and
a processing region (74, 76) that extends in a band shape in a first direction (X) is formed in the second principal surface (4) formed by a plurality of laser marks (71, 72), having a predetermined shape, being arranged regularly along the first direction X.

### APPENDIX 2-2

The semiconductor device (1A to 1E) according to Appendix 2-1, where the predetermined shape of the laser marks (71, 72) includes a line shape that is long along a second direction (Y) orthogonal to the first direction (X).

### APPENDIX 2-3

The semiconductor device (1A to 1E) according to Appendix 2-2, where the line shape is a rectilinear shape or a curved shape extending along the second direction (Y).

### APPENDIX 2-4

The semiconductor device (1A to 1E) according to any one of Appendix 2-1 to Appendix 2-3, where a thickness (TL) of the SiC chip (2) is not less than 50 μm and not more than 350 μm.

### APPENDIX 2-5

The semiconductor device (1A to 1E) according to Appendix 2-4, where the thickness (TL) of the SiC chip (2) is not less than 100 μm and not more than 350 μm.

### APPENDIX 2-6

The semiconductor device (1A to 1E) according to any one of Appendix 2-1 to Appendix 2-5, where the Ra of the second principal surface (4) is not more than 100 nm.

### APPENDIX 2-7

The semiconductor device (1A to 1E) according to any one of Appendix 2-1 to Appendix 2-6, where the metal layer (191) is a silicide layer (191).

### APPENDIX 2-8

The semiconductor device (1A to 1E) according to Appendix 2-7, where the silicide layer (191) is a nickel silicide layer (191) and
the electrode (19, 37, 47) is formed of a metal that includes Ni.

### APPENDIX 2-9

The semiconductor device (1A to 1E) according to any one of Appendix 2-1 to Appendix 2-8, where the first principal surface (3) is a silicon plane and the second principal surface (4) is a carbon plane.

### APPENDIX 2-10

The semiconductor device (1A, 1B) according to any one of Appendix 2-1 to Appendix 2-9, where the element structure (D) includes a Schottky barrier diode (D) that is formed in the first principal surface (3) and has a Schottky metal (19) that forms a Schottky junction with the first principal surface (3).

### APPENDIX 2-11

The semiconductor device (1B) according to Appendix 2-10, where the SiC chip (2) includes a first semiconductor region (7) of a first conductivity type that is formed in a surface layer portion of the first principal surface (3) and a JBS (junction barrier Schottky) structure (23) that is formed by a plurality of semiconductor regions of a second conductivity type selectively formed in a forming region (20) of the Schottky junction in the first principal surface (3).

### APPENDIX 2-12

The semiconductor device (1C, 1E) according to any one of Appendix 2-1 to Appendix 2-9, where the SiC chip (2) includes a first semiconductor region (7, 30) of a first conductivity type that is formed in a surface layer portion of the first principal surface (3) and
the element structure (24) includes a gate trench (25) that is formed in the first principal surface (3), a gate electrode (27) that is embedded in the gate trench (25) with a gate insulating film (26) interposed therebetween, and a second semiconductor region (31, 45) of the first conductivity type and a third semiconductor region (28, 44) of a second conductivity type that are formed successively in a depth direction of the gate trench (25) from the first principal surface (3).

### APPENDIX 2-13

The semiconductor device (1C) according to Appendix 2-12, where the SiC chip (2) includes a drain region (29) of the first conductivity type that is formed in a surface layer portion of the second principal surface (4) and
the second semiconductor region is a source region (31).

### APPENDIX 2-14

The semiconductor device (1E) according to Appendix 2-12, where the SiC chip (2) includes a collector region (43) of the second conductivity type that is formed in a surface layer portion of the second principal surface (4) and
the second semiconductor region is an emitter region (45).

### APPENDIX 2-15

The semiconductor device (1D) according to any one of Appendix 2-1 to Appendix 2-9, where the SiC chip (2) includes a first semiconductor region (7, 30) of a first conductivity type that is formed in a surface layer portion of the first principal surface (3) and
the element structure (24) includes a body region (39) of a second conductivity type and a source region (40) of the first conductivity type in an interior of the body region (39) that are doubly diffused in a surface layer portion of the first semiconductor region (7, 30) and a gate electrode (38) that is formed on the first principal surface (3) with a gate insulating film (42) interposed therebetween and faces a channel region (41) between an outer edge of the body region (39) and an outer edge of the source region (40).

### APPENDIX 3-1

A semiconductor device (1A to 1E) including
an SiC chip (2) that has a first principal surface (3) and a second principal surface (4),
an element structure (D, 24) that is formed in the first principal surface (3), and
an electrode (19, 37, 47) that is formed on the second principal surface (4), is electrically connected to the element structure (D, 24), and includes a metal layer (191) bonded to the second principal surface (4), and
where an arithmetic mean roughness (Ra) of the second principal surface (4) is not less than 30 nm,
the second principal surface (4) has a base region (73, 75) having a first color and dark regions (74, 76) having a second color of darker hue than the first color,
the dark regions (74, 76) are selectively formed in the base region (73, 75) by laser marks (71, 72), respectively extend in a band shape along a first direction (X), and are arranged at intervals along a second direction (Y) orthogonal to the first direction (X).

### APPENDIX 3-2

The semiconductor device (1A to 1E) according to Appendix 3-1, where an aspect ratio (W/L) of a length (L) in the first direction (X) and a width (W) in the second direction (Y) of the dark regions (74, 76) is not more than 0.1.

### APPENDIX 3-3

The semiconductor device (1A to 1E) according to Appendix 3-1 or Appendix 3-2, where a thickness (TL) of the SiC chip (2) is not less than 50 μm and not more than 350 μm.

### APPENDIX 3-4

The semiconductor device (1A to 1E) according to Appendix 3-3, where the thickness (TL) of the SiC chip (2) is not less than 100 μm and not more than 350 μm.

### APPENDIX 3-5

The semiconductor device (1A to 1E) according to any one of Appendix 3-1 to Appendix 3-4, where the Ra of the second principal surface (4) is not more than 100 nm.

### APPENDIX 3-6

The semiconductor device (1A to 1E) according to any one of Appendix 3-1 to Appendix 3-5, where the metal layer (191) is a silicide layer (191).

### APPENDIX 3-7

The semiconductor device (1A to 1E) according to Appendix 3-6, where the silicide layer (191) is a nickel silicide layer (191) and
the electrode (19, 37, 47) is formed of a metal that includes Ni.

### APPENDIX 3-8

The semiconductor device (1A to 1E) according to any one of Appendix 3-1 to Appendix 3-7, where the first principal surface (3) is a silicon plane and the second principal surface (4) is a carbon plane.

### APPENDIX 3-9

The semiconductor device (1A, 1B) according to any one of Appendix 3-1 to Appendix 3-8, where the element structure (D) includes a Schottky barrier diode (D) that is formed in the first principal surface (3) and has a Schottky metal (19) that forms a Schottky junction with the first principal surface (3).

### APPENDIX 3-10

The semiconductor device (1B) according to Appendix 3-9, where the SiC chip (2) includes a first semiconductor region (7) of a first conductivity type that is formed in a surface layer portion of the first principal surface (3) and a JBS (junction barrier Schottky) structure (23) that is formed by a plurality of semiconductor regions of a second conductivity type selectively formed in a forming region (20) of the Schottky junction in the first principal surface (3).

### APPENDIX 3-11

The semiconductor device (1C, 1E) according to any one of Appendix 3-1 to Appendix 3-8, where the SiC chip (2) includes a first semiconductor region (7, 30) of a first conductivity type that is formed in a surface layer portion of the first principal surface (3) and
the element structure (24) includes a gate trench (25) that is formed in the first principal surface (3), a gate electrode (27) that is embedded in the gate trench (25) with a gate insulating film (26) interposed therebetween, and a second semiconductor region (31, 45) of the first conductivity type and a third semiconductor region (28, 44) of a second conductivity type that are formed successively in a depth direction of the gate trench (25) from the first principal surface (3).

### APPENDIX 3-12

The semiconductor device (1C) according to Appendix 3-11, where the SiC chip (2) includes a drain region (29) of the first conductivity type that is formed in a surface layer portion of the second principal surface (4) and
the second semiconductor region is a source region (31).

### APPENDIX 3-13

The semiconductor device (1E) according to Appendix 3-11, where the SiC chip (2) includes a collector region (43) of the second conductivity type that is formed in a surface layer portion of the second principal surface (4) and the second semiconductor region is an emitter region (45).

### APPENDIX 3-14

The semiconductor device (1D) according to any one of Appendix 3-1 to Appendix 3-8, where the SiC chip (2) includes a first semiconductor region (7, 30) of a first conductivity type that is formed in a surface layer portion of the first principal surface (3) and
the element structure (24) includes a body region (39) of a second conductivity type and a source region (40) of the first conductivity type in an interior of the body region (39) that are doubly diffused in a surface layer portion of the first semiconductor region (7, 30) and a gate electrode (38) that is formed on the first principal surface (3) with a gate insulating film (42) interposed therebetween and faces a channel region (41) between an outer edge of the body region (39) and an outer edge of the source region (40).

1. A semiconductor device comprising:
an SiC chip that has a first principal surface and a second principal surface;
an element structure that is formed in the first principal surface; and
an electrode that is formed on the second principal surface, is electrically connected to the element structure, and includes a metal layer bonded to the second principal surface; and
wherein an arithmetic mean roughness (Ra) of the second principal surface is not less than 30 nm and
laser marks formed by mutual overlapping of a plurality of processing units each formed in a quadrangle shape or a circular shape in plan view are formed in the second principal surface.

2. The semiconductor device according to claim 1, wherein a thickness of the SiC chip is not less than 50 μm and not more than 350 μm.

3. The semiconductor device according to claim 2, wherein the thickness of the SiC chip is not less than 100 μm and not more than 350 μm.

4. The semiconductor device according to claim 1, wherein the Ra of the second principal surface is not more than 100 nm.

5. The semiconductor device according to claim 1, wherein each of the processing units is formed, in plan view, to a rectangular shape including a short side and a long side and
a length of the long side is not less than five times a length of the short side.

6. The semiconductor device according to claim 5, wherein the length of the short side of each of the processing units is not less than 0.1 mm and not more than 0.4 mm and the length of the long side of each of the processing units is not less than 1.0 mm and not more than 4.0 mm.

7. The semiconductor device according to claim 1, wherein the metal layer is a silicide layer.

8. The semiconductor device according to claim 7, wherein the silicide layer is a nickel silicide layer and
the electrode is formed of a metal that includes Ni.

9. The semiconductor device according to claim 1, wherein the first principal surface is a silicon plane and the second principal surface is a carbon plane.

10. The semiconductor device according to claim 1, wherein the element structure includes a Schottky barrier diode that is formed in the first principal surface and has a Schottky metal that forms a Schottky junction with the first principal surface.

11. The semiconductor device according to claim 10, wherein the SiC chip includes a first semiconductor region of a first conductivity type that is formed in a surface layer portion of the first principal surface and a JBS (junction barrier Schottky) structure that is formed by a plurality of semiconductor regions of a second conductivity type selectively formed in a forming region of the Schottky junction in the first principal surface.

12. The semiconductor device according to claim 1, wherein the SiC chip includes a first semiconductor region of a first conductivity type that is formed in a surface layer portion of the first principal surface and
the element structure includes a gate trench that is formed in the first principal surface, a gate electrode that is embedded in the gate trench with a gate insulating film interposed therebetween, and a second semiconductor region of the first conductivity type and a third semiconductor region of a second conductivity type that are formed successively in a depth direction of the gate trench from the first principal surface.

13. The semiconductor device according to claim 12, wherein the SiC chip includes a drain region of the first conductivity type that is formed in a surface layer portion of the second principal surface and
the second semiconductor region is a source region.

14. The semiconductor device according to claim 12, wherein the SiC chip includes a collector region of the second conductivity type that is formed in a surface layer portion of the second principal surface and
the second semiconductor region is an emitter region.

15. The semiconductor device according to claim 1, wherein the SiC chip includes a first semiconductor region of a first conductivity type that is formed in a surface layer portion of the first principal surface and
the element structure includes a body region of a second conductivity type and a source region of the first conductivity type in an interior of the body region that are doubly diffused in a surface layer portion of the first semiconductor region and a gate electrode that is formed on the first principal surface with a gate insulating film interposed therebetween and faces a channel region between an outer edge of the body region and an outer edge of the source region.
